(19) United States
(12) Patent Application Publication
(10) Pub. No.: US 2026/0032909 A1
(43) Pub. Date: Jan. 29, 2026

(54) SEMICONDUCTOR MEMORY DEVICE AND METHOD OF MANUFACTURING SEMICONDUCTOR MEMORY DEVICE

(71) Applicant: Kioxia Corporation, Tokyo (JP)

(72) Inventor: Shun SHIMIZU, Yokkaichi (JP)

(73) Assignee: Kioxia Corporation, Tokyo (JP)

(21) Appl. No.: 19/074,668

(22) Filed: Mar. 10, 2025

(30) Foreign Application Priority Data
Jul. 29, 2024 (JP) 2024-122144

(51) Int. Cl. H10B 43/27; H10B 41/27

(52) U.S. Cl. CPC H10B 43/27; H10B 41/27

(57) ABSTRACT

A semiconductor memory device includes a stacked body including conductive layers and insulating layers alternately stacked on top of one another in a first direction; and a dividing portion penetrating the stacked body and extending in the first direction and in a second direction intersecting the first direction. The dividing portion includes: a first film extending in the first direction and the second direction and including a first insulating material; and a second film positioned between the plurality of conductive layers and the first film in a third direction, extending in the first direction and the second direction, having a thinner thickness in the third direction than the first film, and including a second insulating material different from the first insulating material.

### CROSS-REFERENCE TO RELATED APPLICATION

This application is based upon and claims the benefit of priority from Japanese Patent Application No. 2024-122144, Jul. 29, 2024, the entire contents of which are incorporated herein by reference.

### FIELD

Embodiments described herein relate generally to a semiconductor memory device and a method of manufacturing a semiconductor memory device.

### BACKGROUND

A NAND flash memory where memory cells are three-dimensionally arranged is known.

### DESCRIPTION OF THE DRAWINGS

FIG. 1 is a block diagram illustrating a part of a semiconductor memory device according to a first embodiment.

FIG. 2 is a diagram illustrating an equivalent circuit of a part of a memory cell array according to the first embodiment.

FIG. 3 is a cross-sectional view illustrating a part of the semiconductor memory device according to the first embodiment.

FIG. 4 is an enlarged cross-sectional view illustrating a region surrounded by a line F4 of the semiconductor memory device illustrated in FIG. 3.

FIG. 5 is a cross-sectional view taken along a line F5-F5 of the semiconductor memory device illustrated in FIG. 4.

FIG. 6 is a cross-sectional view taken along a line F6-F6 of the semiconductor memory device illustrated in FIG. 3.

FIG. 7 is an enlarged cross-sectional view illustrating a region surrounded by a line F7 of the semiconductor memory device illustrated in FIG. 6.

FIG. 8 is a cross-sectional view illustrating a method of manufacturing the semiconductor memory device according to the first embodiment.

FIG. 9 is a cross-sectional view illustrating the method of manufacturing the semiconductor memory device according to the first embodiment.

FIG. 10 is a cross-sectional view illustrating the method of manufacturing the semiconductor memory device according to the first embodiment.

FIG. 11 is a cross-sectional view illustrating the method of manufacturing the semiconductor memory device according to the first embodiment.

FIG. 12 is a cross-sectional view illustrating the method of manufacturing the semiconductor memory device according to the first embodiment.

FIG. 13 is a cross-sectional view illustrating the method of manufacturing the semiconductor memory device according to the first embodiment.

FIG. 14 is a cross-sectional view illustrating the method of manufacturing the semiconductor memory device according to the first embodiment.

FIG. 15 is a cross-sectional view illustrating the method of manufacturing the semiconductor memory device according to the first embodiment.

FIGS. 16A to 16B are cross-sectional views illustrating a first modification example of the method of manufacturing the semiconductor memory device according to the first embodiment.

FIG. 17 is a cross-sectional view illustrating a second modification example of the method of manufacturing the semiconductor memory device according to the first embodiment.

FIG. 18 is a cross-sectional view illustrating the second modification example of the method of manufacturing the semiconductor memory device according to the first embodiment.

FIG. 19 is a cross-sectional view illustrating a third modification example of the method of manufacturing the semiconductor memory device according to the first embodiment.

FIG. 20 is a cross-sectional view illustrating the method of manufacturing the semiconductor memory device illustrated in FIG. 19.

FIG. 21 is a cross-sectional view illustrating the second modification example of the method of manufacturing the semiconductor memory device according to the first embodiment.

FIG. 22 is a cross-sectional view illustrating the second modification example of the method of manufacturing the semiconductor memory device according to the first embodiment.

FIG. 23 is a cross-sectional view illustrating the second modification example of the method of manufacturing the semiconductor memory device according to the first embodiment.

FIG. 24 is a cross-sectional view illustrating the second modification example of the method of manufacturing the semiconductor memory device according to the first embodiment.

FIG. 25 is a cross-sectional view illustrating the second modification example of the method of manufacturing the semiconductor memory device according to the first embodiment.

FIGS. 26A and 26B are cross-sectional views illustrating a third modification example of the method of manufacturing the semiconductor memory device according to the first embodiment.

FIG. 27 is a cross-sectional view illustrating a first modification example of the semiconductor memory device according to the first embodiment.

FIG. 28 is a plan view illustrating a second modification example of the semiconductor memory device according to the first embodiment.

FIG. 29 is a cross-sectional view illustrating a third modification example of the semiconductor memory device according to the first embodiment.

FIGS. 30A to 30C are cross-sectional views illustrating the method of manufacturing the semiconductor memory device illustrated in FIG. 29.

FIG. 31 is a cross-sectional view illustrating a fourth modification example of the semiconductor memory device according to the first embodiment.

FIG. 32 is a cross-sectional view illustrating a fifth modification example of the semiconductor memory device according to the first embodiment.

FIG. 33 is a cross-sectional view illustrating a sixth modification example of the semiconductor memory device according to the first embodiment.

FIG. 34 is a cross-sectional view illustrating a seventh modification example of the semiconductor memory device according to the first embodiment.

FIG. 35 is a cross-sectional view illustrating advantageous effects of the seventh modification example of the first embodiment.

### DETAILED DESCRIPTION

Embodiments provide a semiconductor memory device and a method of manufacturing a semiconductor memory device capable of improving electrical characteristics.

In general, according to one embodiment, a semiconductor memory device includes a stacked body including a plurality of conductive layers and a plurality of insulating layers, wherein the plurality of conductive layers and the plurality of insulating layers are alternately stacked on top of one another in a first direction; and a dividing portion penetrating the stacked body and extending in the first direction and in a second direction intersecting the first direction. When a direction intersecting the first direction and the second direction is a third direction, the dividing portion includes: a first film extending in the first direction and the second direction and including a first insulating material; and a second film positioned between the plurality of conductive layers and the first film in the third direction, extending in the first direction and the second direction, having a thinner thickness in the third direction than the first film, and including a second insulating material different from the first insulating material.

Hereinafter, a semiconductor memory device and a method of manufacturing the semiconductor memory device according to an embodiment will be described with reference to the drawings. In the following description, components having the same or equivalent function are represented by the same reference numeral. The repeated description of the components may not be made. In the following description, when reference numerals where a numeral or an alphabetical character is added to an end for distinction do not need to be distinguished from each other, the numeral or the alphabetical character of the end may be removed.

In the present application, terms are defined as follows. “Parallel”, “perpendicular”, or “the same” may include “substantially parallel”, “substantially perpendicular”, or “substantially the same”, respectively. “Connection” may include not only mechanical connection but also electrical connection. That is, “connection” is not limited to a case where a plurality of elements are directly connected and may include a case where a plurality of elements are connected with another element interposed therebetween. “Overlap” is not limited to a case where a plurality of elements are in contact with each other and may include a case where a plurality of elements are distant from each other (a case where projection images of a plurality of elements overlap each other when seen from one direction).

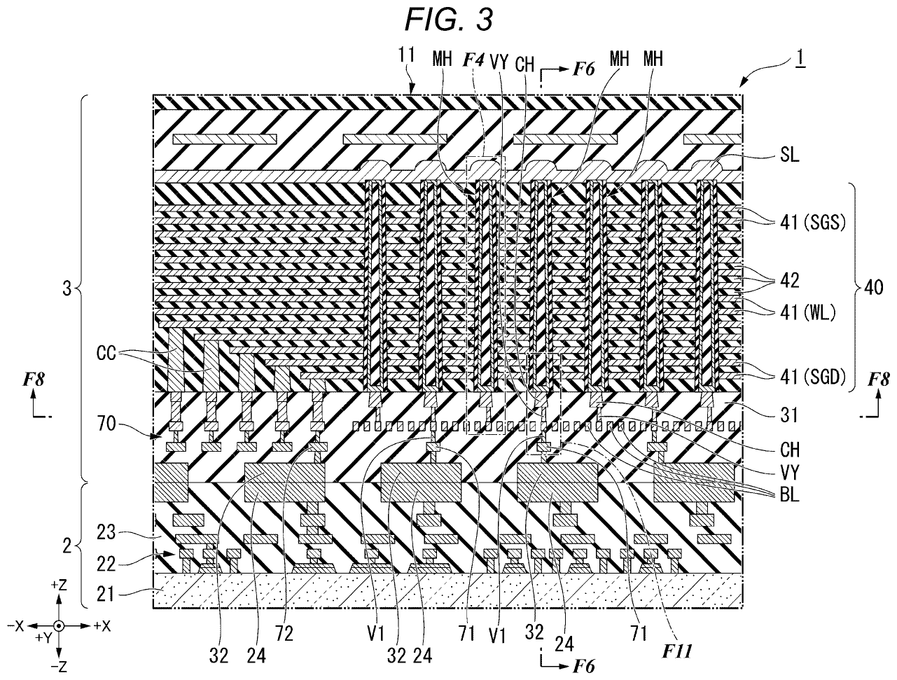

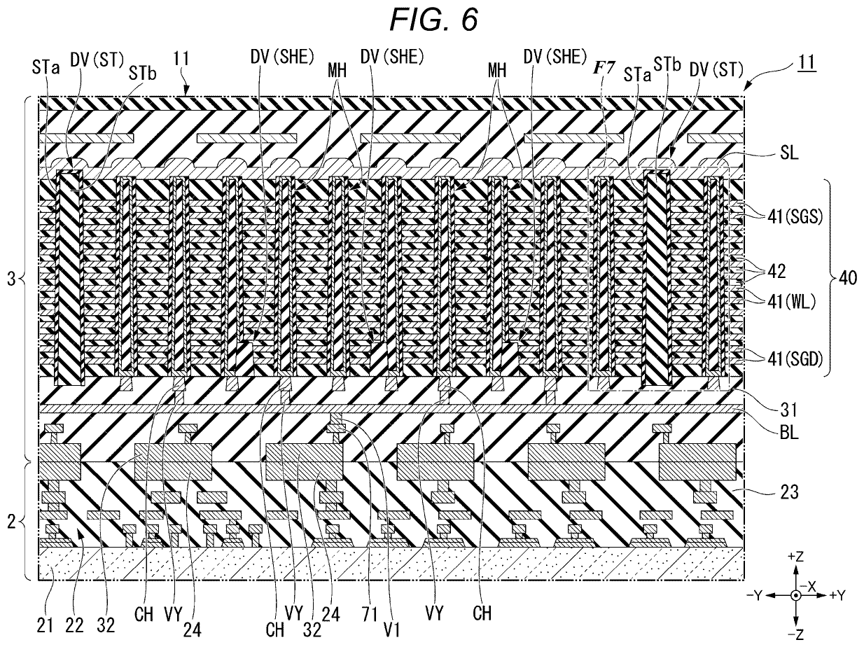

A +X direction, a −X direction, a +Y direction, a −Y direction, a +Z direction, and a −Z direction are defined as follows. The +X direction is a direction in which a word line WL described below extends (refer to FIG. 3). The −X direction is a direction opposite to the +X direction. When the +X direction and the −X direction do not need to be distinguished from each other, the +X direction and the −X direction will be simply referred to as the X direction. The +Y direction is a direction intersecting (for example, perpendicular to) the X direction. The +Y direction is a direction in which a bit line BL extends (refer to FIG. 6). The −Y direction is a direction opposite to the +Y direction. When the +Y direction and the −Y direction do not need to be distinguished from each other, the +Y direction and the −Y direction will be simply referred to as the Y direction. The +Z direction is a direction intersecting (for example, perpendicular to) the X direction and the Y direction. The +Z direction is a direction from a bit line BL described below toward a stacked body 40 (refer to FIG. 3). The −Z direction is a direction opposite to the +Z direction. When the +Z direction and the −Z direction do not need to be distinguished from each other, the +Z direction and the −Z direction will be simply referred to as the Z direction.

In the present application, the +Z direction side will also be referred to as “upper”, and the −Z direction side will also be referred to as “lower”. In addition, in the present application, a position in the Z direction will also be referred to as “height”. Here, these expressions are used for convenience of description and does not define the gravity direction. The Z direction is an example of “first direction”. The X direction corresponds to an example of “second direction”. The Y direction corresponds to an example of “third direction”. In addition, in the drawings described below, a configuration that does not relate to the description is not illustrated.

### First Embodiment

### 1. Configuration of Semiconductor Memory Device

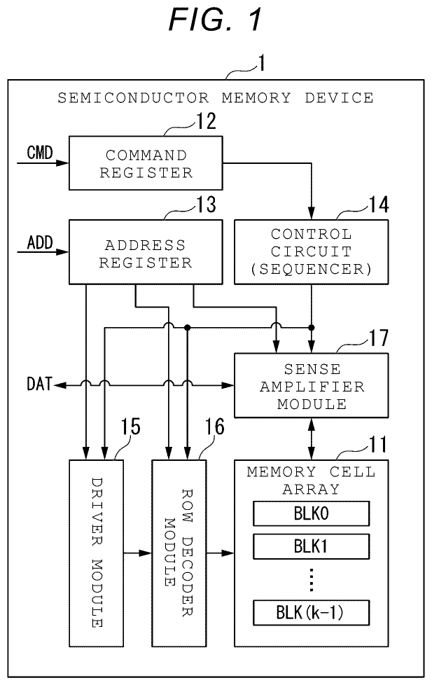

FIG. 1 is a block diagram illustrating a part of a semiconductor memory device 1 according to a first embodiment. The semiconductor memory device 1 is a nonvolatile semiconductor memory device such as a NAND flash memory. The semiconductor memory device 1 can be connected to an external host device and is used as a storage space of the host device. The semiconductor memory device 1 includes, for example, a memory cell array 11, a command register 12, an address register 13, a control circuit (sequencer) 14, a driver module 15, a row decoder module 16, and a sense amplifier module 17.

The memory cell array 11 includes a plurality of blocks BLK0 to BLK(k−1) (k represents an integer of 1 or more). The block BLK is a set including memory cell transistors. The block BLK is used as a unit of erasing data. In the memory cell array 11, a plurality of bit lines and a plurality of word lines are provided. Each of the memory cell transistors is associated with one bit line and one word line.

The command register 12 stores a command CMD that is received from the host device by the semiconductor memory device 1. The address register 13 stores address information ADD that is received from the host device by the semiconductor memory device 1. The address information ADD is used for selecting a block BLK, a word line, and a bit line. The control circuit 14 controls various operations of the semiconductor memory device 1. For example, the control circuit 14 executes a write operation, a read operation, or an erasing operation of data based on the command CMD stored in the command register 12.

The driver module 15 includes a voltage generation circuit and generates voltages used in various operations of the semiconductor memory device 1. The row decoder module 16 transmits, for example, a voltage applied to a signal line corresponding to a selected word line to the selected word line. The sense amplifier module 17 applies a desired voltage to each of bit lines in the write operation. In addition, in the read operation, the sense amplifier module 17 determines data stored in each of the memory cell transistors based on the voltage of each of the bit lines, and transmits the determination result to the host device as read data DAT.

### 2. Electrical Configuration of Memory Cell Array

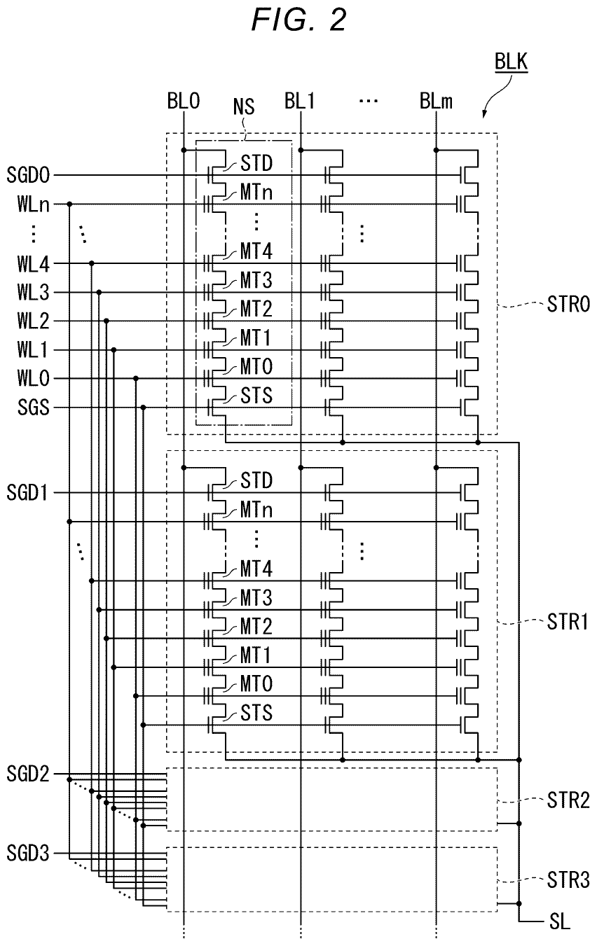

FIG. 2 is a diagram illustrating an equivalent circuit of a part of the memory cell array 11. FIG. 2 illustrates one block BLK in the memory cell array 11. The block BLK includes a plurality of strings STR (for example, five strings STR0 to STR4).

Each of the strings STR includes a plurality of NAND strings NS that are associated with bit lines BL0 to BLm (m represents an integer of 1 or more), respectively. Each of the NAND strings NS includes a plurality of memory cell transistors MT0 to MTn (n represents an integer of 1 or more), one or more drain-side select transistors STD, and one or more source-side select transistors STS.

In each of the NAND strings NS, the memory cell transistors MT0 to MTN are connected in series to each other. Each of the memory cell transistors MT includes a control gate and a charge storage unit. The control gate of the memory cell transistor MT is connected to any of word lines WL0 to WLn. Each of the memory cell transistors MT stores charge in the charge storage unit according to a voltage applied to the control gate via the word line WL, and stores data in a nonvolatile manner.

A drain of the drain-side select transistor STD is connected to the bit line BL corresponding to the NAND string NS. A source of the drain-side select transistor STD is connected to a first end of the memory cell transistors MT0 to MTn that are connected in series to each other. A control gate of the drain-side select transistor STD is connected to any of drain-side select gate lines SGD0 to SGD3. The drain-side select transistor STD is electrically connected to the row decoder module 16 via the drain-side select gate line SGD. When a predetermined voltage is applied to the corresponding drain-side select gate line SGD, the drain-side select transistor STD connects the NAND string NS and the bit line BL to each other.

A drain of the source-side select transistor STS is connected to a second end of the memory cell transistors MT0 to MTn that are connected in series to each other. A source of the source-side select transistor STS is connected to a source line SL. A control gate of the source-side select transistor STS is connected to a source-side select gate line SGS. When a predetermined voltage is applied to the corresponding source-side select gate line SGS, the source-side select transistor STS connects the NAND string NS and the source line SL to each other.

In the same block BLK, control gates of the memory cell transistors MT0 to MTn are connected in common to corresponding word lines WL0 to WLn, respectively. In the same strings STR, the control gate of the drain-side select transistor STD is connected in common to the corresponding drain-side select gate line SGD. The control gate of the source-side select transistor STS is connected in common to the source-side select gate line SGS. In the memory cell array 11, the bit line BL is shared by the NAND strings NS to which the same column address is allocated in the plurality of strings STR.

### 3. Structure of Semiconductor Memory Device

Next, a structure of the semiconductor memory device 1 will be described.

FIG. 3 is a cross-sectional view illustrating a part of the semiconductor memory device 1. The semiconductor memory device 1 includes, for example, a first chip 2 and a second chip 3. The second chip 3 is a chip bonded to the first chip 2.

### 3.1 First Chip

The first chip 2 is a circuit chip including a peripheral circuit. The first chip 2 includes, for example, a semiconductor substrate 21, a peripheral circuit 22, an insulating portion 23, and a plurality of pads 24.

The semiconductor substrate 21 is, for example, a substrate that is a base of the first chip 2. At least a part of the semiconductor substrate 21 has a plate shape in the X direction and the Y direction. The semiconductor substrate 21 is formed of a semiconductor material such as silicon.

The peripheral circuit 22 is a circuit for allowing the above-described memory cell array 11 to function. The peripheral circuit 22 includes one or more among the command register 12, the address register 13, the control circuit 14, the driver module 15, the row decoder module 16, and the sense amplifier module 17 described above. The insulating portion 23 covers the peripheral circuit 22. The plurality of pads 24 are provided on a surface of the insulating portion 23. Each of the pads 24 is electrically connected to the peripheral circuit 22.

### 3.2 Second Chip

The second chip 3 is an array chip that includes the memory cell array 11. The second chip 3 includes, for example, the memory cell array 11, an insulating portion 31, and a plurality of pads 32. Here, the insulating portion 31 and the plurality of pads 32 will be described, and the memory cell array 11 will be described below.

The insulating portion 31 covers the memory cell array 11 from the −Z direction side. The plurality of pads 32 are provided on a surface of the insulating portion 31. Each of the pads 32 is electrically connected to a wiring (for example, a wiring 71 or a wiring 72) in a wiring portion 70 of the memory cell array 11 described below. In the present embodiment, by bonding the plurality of pads 24 of the first chip 2 and the plurality of pads 32 of the second chip 3 to face each other, the first chip 2 and the second chip 3 are integrated with each other.

### 4. Physical Configuration of Memory Cell Array

Next, a physical configuration of the memory cell array 11 will be described.

As illustrated in FIG. 3, the memory cell array 11 includes, for example, a stacked body 40, a source line SL, a plurality of memory pillars MH, a plurality of bit lines BL, a plurality of contacts CH for the memory pillars MH, a plurality of contacts VY for the memory pillars MH, a contact CC for a conductive layer, the wiring portion 70, and a plurality of dividing portions DV (refer to FIG. 6).

### 4.1 Stacked Body

First, the stacked body 40 will be described.

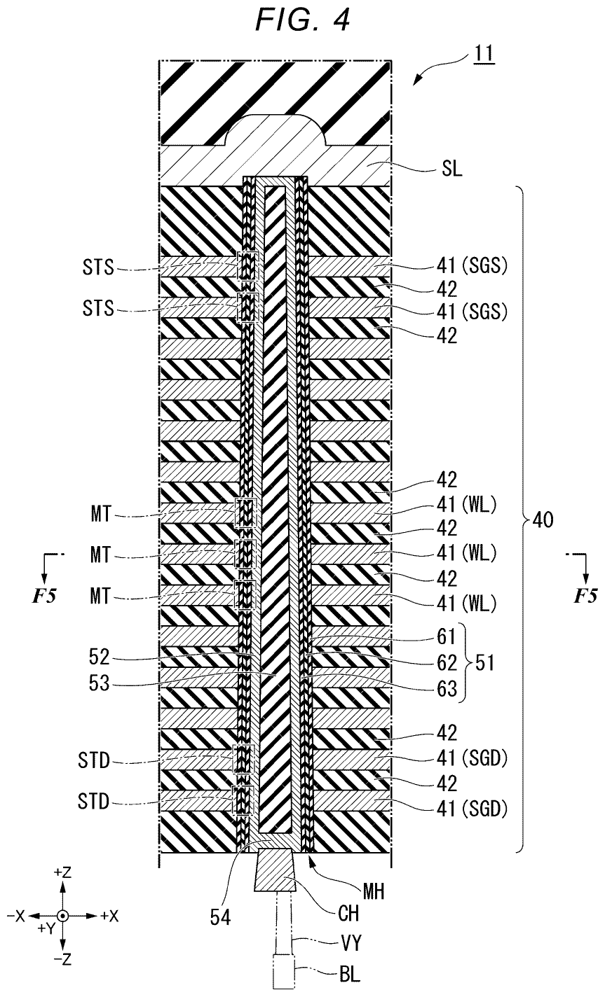

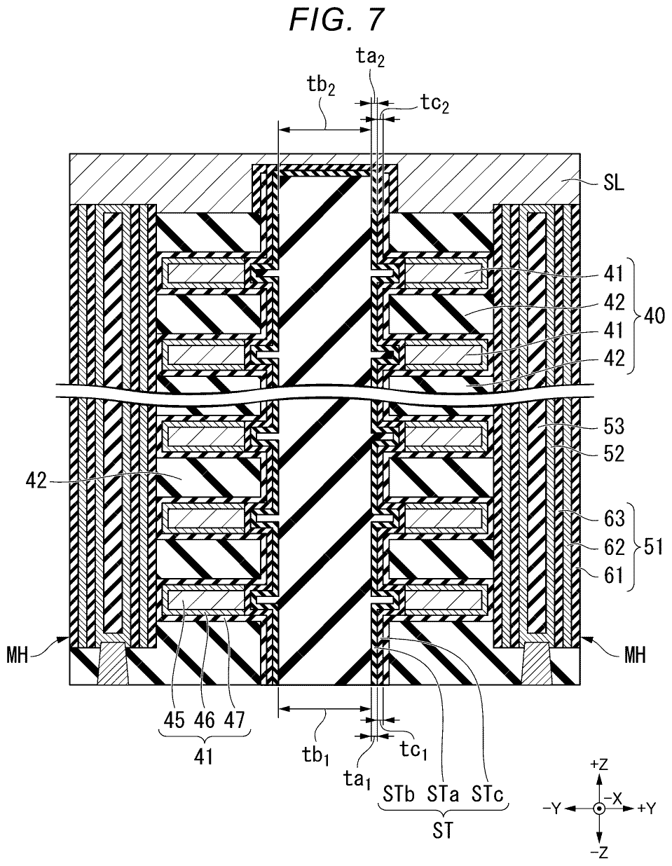

FIG. 4 is an enlarged cross-sectional view illustrating a region surrounded by a line F4 of the memory cell array 11 illustrated in FIG. 3. FIG. 6 is a cross-sectional view taken along a line F6-F6 of the semiconductor memory device 1 illustrated in FIG. 3. FIG. 7 is an enlarged cross-sectional view illustrating a region surrounded by a line F7 of the semiconductor memory device illustrated in FIG. 6. The stacked body 40 includes, for example, a plurality of conductive layers 41 and a plurality of insulating layers 42. The plurality of conductive layers 41 and the plurality of insulating layers 42 are stacked one by one alternately in the Z direction.

### 4.2 Conductive Layer

As illustrated in FIGS. 3, 4, 6, and 7, each of the conductive layers 41 is provided in the X direction and the Y direction. As illustrated in FIG. 7, each of the conductive layers 41 includes a conductive portion 45, a barrier metal film 46, and an insulating film 47.

The conductive portion 45 is provided in the X direction and the Y direction. The conductive portion 45 includes a conductive material. The conductive portion 45 is formed of, for example, tungsten, molybdenum, or silicon doped with impurity.

The barrier metal film 46 is provided along a surface in the Z direction, a surface in the X direction, and a surface in the Y direction on the memory pillar MH side in the conductive portion 45. The insulating film 47 is provided along a surface in the Z direction, a surface in the X direction, and a surface in the Y direction on the memory pillar MH side in the barrier metal film 46. As a result, the barrier metal film 46 is positioned between the conductive portion 45 and the insulating film 47. Further, the insulating film 47 is provided along a surface in the Y direction on a dividing portion ST side in the insulating layer 42. That is, the insulating film 47 penetrates the stacked body 40 and extends in the Z direction and the X direction (refer to FIG. 7).

The barrier metal film 46 is a film for preventing diffusion of the conductive material in the conductive portion 45. The barrier metal film 46 includes, for example, a material including titanium, a material including titanium and nitrogen, a material including tantalum, a material including tantalum and nitrogen, or a material including tungsten and nitrogen.

The insulating film 47 improves breakdown voltage characteristics of the conductive layer 41. The insulating film 47 is formed of, for example, a film (for example, an aluminum oxide film) including aluminum and oxygen.

As illustrated in FIGS. 3, 4, and 6, one or more (for example, a plurality of) conductive layers 41 positioned on the lower side among the plurality of conductive layers 41 function as the drain-side select gate line SGD. The drain-side select gate line SGD is provided in common for the plurality of memory pillars MH arranged in the X direction or the Y direction. An intersection between the drain-side select gate line SGD and a channel layer 52 (described below) of each of the memory pillars MH functions as the above-described drain-side select transistor STD.

One or more (for example, a plurality of) conductive layers 41 positioned on the upper side among the plurality of conductive layers 41 function as the source-side select gate line SGS. The source-side select gate line SGS is provided in common for the plurality of memory pillars MH arranged in the X direction or the Y direction. An intersection between the source-side select gate line SGS and the channel layer 52 (described below) of each of the memory pillars MH functions as the above-described source-side select transistor STS.

At least a part of the remaining conductive layers 41 provided between the conductive layers 41 that function as the drain-side select gate line SGD and the source-side select gate line SGS among the plurality of conductive layers 41 functions as the word line WL. The word line WL is provided in common for the plurality of memory pillars MH arranged in the X direction and the Y direction. In the present embodiment, an intersection between the word line WL and the channel layer 52 of each of the memory pillars MH functions as the memory cell transistor MT.

### 4.2 Insulating Layer

The insulating layer 42 is provided between two conductive layers 41 adjacent to each other in the Z direction and is an interlayer insulating film that insulates the two conductive layers 41. The insulating layer 42 is provided in the X direction and the Y direction. The insulating layer 42 is formed of, for example, a film (for example, a silicon oxide film) including silicon and oxygen.

### 4.4 Source Line

The source line SL is disposed above the stacked body 40. The source line SL is formed of, for example, a conductive layer or a semiconductor layer that spreads in the X direction and the Y direction. The source line SL is formed of a conductive material such as tungsten or molybdenum or a semiconductor material including silicon.

### 4.5 Memory Pillar

The plurality of memory pillars MH are arranged in the X direction and the Y direction (refer to FIG. 3). Each of the memory pillars MH extends in the Z direction in the stacked body 40 and penetrates the stacked body 40. An upper end of the memory pillar MH is in contact with the source line SL. On the other hand, a lower end of each of the memory pillars MH is in contact with the contact CH described below. The memory pillar MH is an example of “columnar body”.

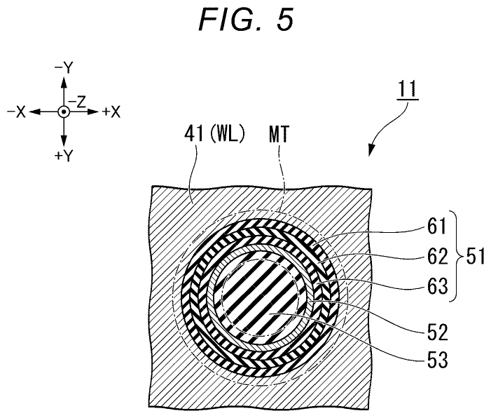

FIG. 5 is a cross-sectional view taken along a line F5-F5 of the semiconductor memory device 1 illustrated in FIG. 4. The memory pillar MH includes, for example, a memory film (multilayer film) 51, the channel layer 52, an insulating core 53, and a cap portion 54 (refer to FIG. 4).

The memory film 51 is provided on an outer peripheral side of the channel layer 52. The memory film 51 is positioned between the plurality of conductive layers 41 and the channel layer 52. The memory film 51 includes, for example, a block insulating film 61, a charge trapping film 62, and a tunnel insulating film 63.

The block insulating film 61 is provided between the plurality of conductive layers 41 and the charge trapping film 62. The block insulating film 61 is an insulating film that prevents back tunneling. The back tunneling is a phenomenon in which charge returns from the word line WL to the charge trapping film 62. The block insulating film 61 is formed in an annular shape and extends in the Z direction. The block insulating film 61 is provided across, for example, the entire length of the memory pillar MH in the Z direction. The block insulating film 61 is a film having a stacked structure where a plurality of insulating films such as a film including silicon and oxygen or a film including a metal and oxygen are stacked. One example of the film including a metal and oxygen is aluminum oxide. The block insulating film 61 may include a high dielectric constant material (High-k material) such as silicon nitride or hafnium oxide.

The charge trapping film 62 is positioned between the block insulating film 61 and the tunnel insulating film 63. The charge trapping film 62 is formed in an annular shape and extends in the Z direction. The charge trapping film 62 is provided across, for example, the entire length of the memory pillar MH in the Z direction. The charge trapping film 62 includes many crystal defects (trapping levels) and is a functional film capable of trapping charge in the crystal defects. The charge trapping film 62 is formed of, for example, a film including silicon and nitrogen. A portion adjacent to each of the word lines WL in the charge trapping film 62 is an example of “charge storage unit” that can store information by storing charge.

The tunnel insulating film 63 is provided between the channel layer 52 and the charge trapping film 62. The tunnel insulating film 63 has, for example, an annular shape along an outer peripheral surface of the channel layer 52, and extends in the Z direction along the channel layer 52. The tunnel insulating film 63 is provided across, for example, the entire length of the memory pillar MH in the Z direction. The tunnel insulating film 63 is a potential barrier between the channel layer 52 and the charge trapping film 62. The tunnel insulating film 63 is formed of a film including silicon and oxygen or a film including silicon, oxygen, and nitrogen.

The channel layer 52 is provided inside the memory film 51. The channel layer 52 is formed in an annular shape. The channel layer 52 extends in the Z direction. The channel layer 52 is provided across, for example, the entire length of the memory pillar MH in the Z direction. The channel layer 52 is formed of a semiconductor material such as polysilicon. The channel layer 52 may be doped with impurity. When a voltage is applied to the word line WL, the channel layer 52 forms a channel to electrically connect the bit line BL and the source line SL.

As a result, at the same height as that of each of the word lines WL, a metal-Al-Nitride-Oxide-Silicon (MANOS) type memory cell transistor MT is formed using an end portion of the word line WL adjacent to the memory pillar MH, the block insulating film 61, the charge trapping film 62, the tunnel insulating film 63, and the channel layer 52. The memory film 51 may include a floating gate type charge storage unit (floating gate electrode) as the charge storage unit instead of the charge trapping film 62. The floating gate electrode is formed of, for example, a polysilicon including impurity.

The insulating core 53 is provided inside the channel layer 52. At least a part of the inside of the channel layer 52 is embedded in the insulating core 53. The insulating core 53 is formed of a film including silicon and oxygen. A part of the insulating core 53 may be formed in an annular shape along an inner peripheral surface of the channel layer 52, and may include a cavity portion (air gap) thereon. The insulating core 53 extends in the Z direction. The insulating core 53 is provided across, for example, most of the memory pillar MH in the Z direction excluding an upper end portion of the memory pillar MH (refer to FIG. 4).

Next, the cap portion 54 will be described referring back to FIG. 4. The cap portion 54 is provided below the insulating core 53. The cap portion 54 is a semiconductor portion formed of a semiconductor material such as amorphous silicon or polysilicon. The cap portion 54 may be doped with impurity. The cap portion 54 is disposed on an inner peripheral side of a lower end portion of the memory film 51 and is formed to be integrated with the channel layer 52. The cap portion 54 forms not only a lower end portion of the channel layer 52 but also a lower end portion of the memory pillar MH. The contact CH is in contact with the cap portion 54 in the −Z direction.

### 4.6 Bit Line

Next, the bit line BL will be described referring back to FIG. 3. The bit line BL is a wiring for selecting one memory pillar MH from the plurality of memory pillars MH. The plurality of bit lines BL are disposed below (−Z direction side) the stacked body 40. The plurality of bit lines BL are arranged in the X direction at intervals in the X direction. Each of the bit lines BL extends in the Y direction. Each of the bit lines BL extends to pass through the region below the corresponding plurality of memory pillars MH.

Each of the bit lines BL is connected to the channel layer 52 of the memory pillar MH through the contact VY and the contact CH. As a result, by combining the word line WL and the bit line BL, any memory cell transistor MT can be selected from the plurality of memory cell transistors MT that are three-dimensionally arranged.

### 4.7 Contact CH for Memory Pillar

The plurality of contacts CH are disposed between the plurality of memory pillars MH and the plurality of bit lines BL. Each of the contacts CH is an electrical connection portion that electrically connects the contact VY and the memory pillar MH. The contact CH has, for example, a columnar or a truncated conical shape. When seen from the Z direction, for example, an external shape of the contact CH is the same as or less than an external shape of the memory pillar MH.

The contact CH is disposed below the corresponding memory pillar MH and is in contact with the lower end of the memory pillar MH. The contact CH is in contact with, for example, the cap portion 54 of the memory pillar MH (refer to FIG. 4). The contact CH is formed of, for example, a metal material such as tungsten or molybdenum.

### 4.8 Contact VY for Memory Pillar

The plurality of contacts VY are disposed between the plurality of contacts CH and the plurality of bit lines BL. Each of the contact VY is an electrical connection portion that electrically connects the bit line BL and the contact CH. The width of the contact VY in the X direction is less than the width of the contact CH in the X direction.

The contact VY is disposed above the corresponding bit line BL, and a lower end of the contact CH and the bit line BL are in contact with each other. In the X direction, the contact VY is disposed at a position shifted from the center of the contact CH and the center of the memory pillar MH. The contact VY is formed of, for example, a metal material such as tungsten or molybdenum. The material for forming the contact VY is the same as, for example, the material for forming the contact CH.

### 4.9 Contact for Conductive Layer

As illustrated in FIG. 3, the contact CC is an electrical connection portion that electrically connects the conductive layer 41 and the wiring 72 (described below) in the wiring portion 70. The plurality of contacts CC are disposed corresponding to a stepwise region where end portions of the plurality of conductive layers 41 in the stacked body 40 are disposed stepwise. The plurality of contacts CC extend in the Z direction and are different from, for example, the length in the Z direction. An upper end of each of the contacts CC is in contact with the corresponding conductive layer 41. The upper end of each of the contacts CC is electrically connected to the corresponding conductive layer 41.

### 4.10 Wiring Portion

Next, the wiring portion 70 will be described. For example, the wiring portion 70 is disposed between the stacked body 40 and the semiconductor substrate 21. The wiring portion 70 includes, for example, a plurality of wirings 71, a plurality of vias V1, and a plurality of wirings 72.

The wiring 71 is an electrical connection portion that electrically connects the bit line BL and the pad 32. The plurality of wirings 71 are disposed below, for example, the plurality of bit lines BL. Each of the wirings 71 extends, for example, in the X direction or the Y direction. The via V1 that electrically connects the wiring 71 and the bit line BL is provided between the wiring 71 and the bit line BL.

The wiring 72 is an electrical connection portion that electrically connects the contact CC for a conductive layer and the pad 32. The wiring 72 is electrically connected to the conductive layer 41 through the contact CC for a conductive layer. A voltage is applied to the wiring 72 to select the conductive layer 41 (the word line WL, the drain-side select gate line SGD, or the source-side select gate line SGS).

### 5. Dividing Portion of Stacked Body

Next, the dividing portions DV will be described.

FIG. 6 is a cross-sectional view taken along the line F6-F6 of the semiconductor memory device 1 illustrated in FIG. 3. In the present embodiment, the plurality of dividing portions DV are provided in the stacked body 40. The plurality of dividing portions DV are disposed to be divided in the Y direction. The plurality of dividing portions DV extend in the Z direction in the stacked body 40, and divides one or more conductive layers 41 including the lowermost layer among the plurality of conductive layers 41 in the Y direction. The plurality of dividing portions DV includes, for example, a plurality of dividing portions ST and a plurality of dividing portions SHE.

### 5.1 Dividing Portion ST

Next, the dividing portion ST will be described.

FIG. 7 is an enlarged cross-sectional view illustrating the region surrounded by the line F7 of the semiconductor memory device illustrated in FIG. 6. The dividing portion ST in the present embodiment is a wall portion that divides the stacked body 40 in the Y direction. The plurality of dividing portions ST are disposed to be divided in the Y direction. The plurality of dividing portions ST extend in the Z direction, penetrate the stacked body 40, and extend in the X direction. That is, the dividing portion ST is a wall portion provided in the Z direction and the X direction. The dividing portion ST divides each of all of the conductive layers 41 in the stacked body 40 in the Y direction.

As illustrated in FIG. 7, the dividing portion ST includes an embedded insulating film STb, a diffusion barrier layer STa, and a side wall insulating film STc (not illustrated in FIG. 6). The embedded insulating film STb is an example of “first film”. The diffusion barrier layer STa is an example of “second film”. The side wall insulating film STc is an example of “third film”.

As illustrated in FIG. 7, the embedded insulating film STb, the diffusion barrier layer STa, and the side wall insulating film STc that form the dividing portion ST are embedded in a region where the conductive layer 41 is not present between the adjacent insulating layers 42. As a result, at a position of the dividing portion ST in contact with the conductive layer 41, the embedded insulating film STb, the diffusion barrier layer STa, and the side wall insulating film STc protrude toward the conductive layer 41.

The embedded insulating film STb extends in the Z direction and the X direction. The embedded insulating film STb has insulating characteristics and penetrates the stacked body 40. The embedded insulating film STb is formed of, for example, a film including silicon and oxygen.

In the present embodiment, as illustrated in FIG. 7, the diffusion barrier layer STa and the side wall insulating film STc are disposed between the embedded insulating film STb and the source line SL, and the diffusion barrier layer STa and the side wall insulating film STc are continuously provided to surround the embedded insulating film STb.

As illustrated in FIG. 7, the diffusion barrier layer STa is positioned between the conductive layer 41 and the embedded insulating film STb in the Y direction. In addition, the diffusion barrier layer STa is positioned between the source line SL and the embedded insulating film STb in the Z direction.

The diffusion barrier layer STa positioned between the conductive layer 41 and the embedded insulating film STb extends in the Z direction and the X direction and penetrates the stacked body 40. A thickness ta of the diffusion barrier layer STa in the Y direction is less than a thickness tb of the embedded insulating film STb in the Y direction.

In the present specification, the thickness tb of the embedded insulating film STb in the Y direction is an average thickness of a thickness (distance between both end portions in the Y direction) tb₁ in the Y direction on one side (lower side in FIG. 7) of the stacked body 40 in the Z direction and a thickness (distance between both end portions in the Y direction) tb₂ in the Y direction on a side (upper side in FIG. 7) of the stacked body 40 opposite to the one side in the Z direction.

When a cavity is formed in the embedded insulating film STb, the thickness tb of the embedded insulating film STb in the Y direction also includes the cavity of the embedded insulating film STb.

In addition, in the present specification, the thickness ta of the diffusion barrier layer STa in the Y direction is an average thickness of a thickness tai in the Y direction on one side (lower side in FIG. 7) of the stacked body 40 in the Z direction and a thickness ta in the Y direction on a side (upper side in FIG. 7) of the stacked body 40 opposite to the one side in the Z direction.

A thickness tc of the side wall insulating film STc in the Y direction is an average thickness of a thickness tc₁ in the Y direction on one side (lower side in FIG. 7) of the stacked body 40 in the X direction and a thickness tc₂ in the Y direction on a side (upper side in FIG. 7) of the stacked body 40 opposite to the one side in the X direction.

The diffusion barrier layer STa is a film that prevents diffusion of impurity such as hydrogen in the embedded insulating film STb, improves reliability of the memory cell array 11, and improves electrical characteristics of the semiconductor memory device 1. A material of the diffusion barrier layer STa may be a material different from that of the embedded insulating film STb and may be a material capable of preventing diffusion of impurity in the embedded insulating film STb. Accordingly, the diffusion barrier layer STa may have conductivity or may have insulating characteristics.

The material of the diffusion barrier layer STa may include silicon and nitrogen, or may include aluminum, hafnium, zirconium, or titanium. The diffusion barrier layer STa may include, for example, a material including nitrogen and one or more selected from among aluminum, hafnium, zirconium, and titanium or a material including oxygen and one or more selected from among aluminum, hafnium, zirconium, and titanium.

The side wall insulating film STc extends in the Z direction and the X direction and penetrates the stacked body 40. The side wall insulating film STc is positioned between the conductive layer 41 and the diffusion barrier layer STa in the Y direction. In addition, the side wall insulating film STc is positioned between the source line SL and the diffusion barrier layer STa in the Z direction. The side wall insulating film STc has insulating characteristics and includes a material different from that of the diffusion barrier layer STa.

The side wall insulating film STc is optionally provided. When the diffusion barrier layer STa has insulating characteristics and also functions as the side wall insulating film STc, the side wall insulating film STc does not need to be provided. When the diffusion barrier layer STa has conductivity, it is preferable that the side wall insulating film STc is provided. The side wall insulating film STc is formed of, for example, a film including silicon and oxygen. In addition, the thickness tc of the side wall insulating film STc in the Y direction less than the thickness tb of the embedded insulating film STb in the Y direction.

The thickness of the side wall insulating film STc in the Y direction is preferably 5 nm to 10 nm. When the thickness of the side wall insulating film STc in the Y direction is 5 nm or more, higher insulating characteristics can be obtained. In addition, when the thickness of the side wall insulating film STc in the Y direction is 10 nm or less, diffusion of hydrogen from the side wall insulating film STc to the conductive layer 41 can be prevented, and reliability of the memory cell array 11 is further improved.

Only the diffusion barrier layer STa or the side wall insulating film STc may be disposed between the embedded insulating film STb that forms the dividing portion ST and the source line SL, or the embedded insulating film STb may be in contact with the source line SL in the Z direction. Accordingly, a pair of diffusion barrier layers STa that are divided in the Y direction by the embedded insulating film STb may be used. In addition, a pair of side wall insulating films STc that are divided in the Y direction by the embedded insulating film STb may be used.

### 5.2 Dividing Portion SHE

The dividing portion SHE is a dividing portion that is shallower in the Z direction than the dividing portion ST, and is a wall portion that divides a lower end portion of the stacked body 40 in the Y direction. The plurality of dividing portions SHE are disposed to be divided in the Y direction. In the present embodiment, a plurality of (for example, three) dividing portions SHE are present between two dividing portions ST adjacent to each other in the Y direction. The dividing portion SHE is provided in the lower end portion of the stacked body 40, extends up to the middle of the stacked body 40 in the Z direction, and extends in the X direction. That is, the dividing portion SHE is a wall portion provided in the Z direction and the X direction.

The dividing portion SHE penetrates a part of the conductive layers 41 including the lowermost layer among the plurality of conductive layers 41, and divides the part of the conductive layers 41 in the Y direction. For example, the dividing portion SHE penetrates each of all the conductive layers 41 that function as the drain-side select gate line SGD. On the other hand, the dividing portion SHE does not reach the conductive layer 41 that functions as the word line WL. The dividing portion SHE divides only the conductive layer 41 that functions as the drain-side select gate line SGD in the Y direction. The dividing portion SHE is formed of, for example, a film including silicon and oxygen.

### 6. Method of Manufacturing Semiconductor Memory Device

Next, a method of manufacturing the semiconductor memory device 1 will be described. Hereinafter, steps relating to the formation of the dividing portion ST will be described in detail. The details of the other manufacturing steps are described in, for example, JP-A-2022-41054. The entirety of this document is incorporated in the present specification by reference.

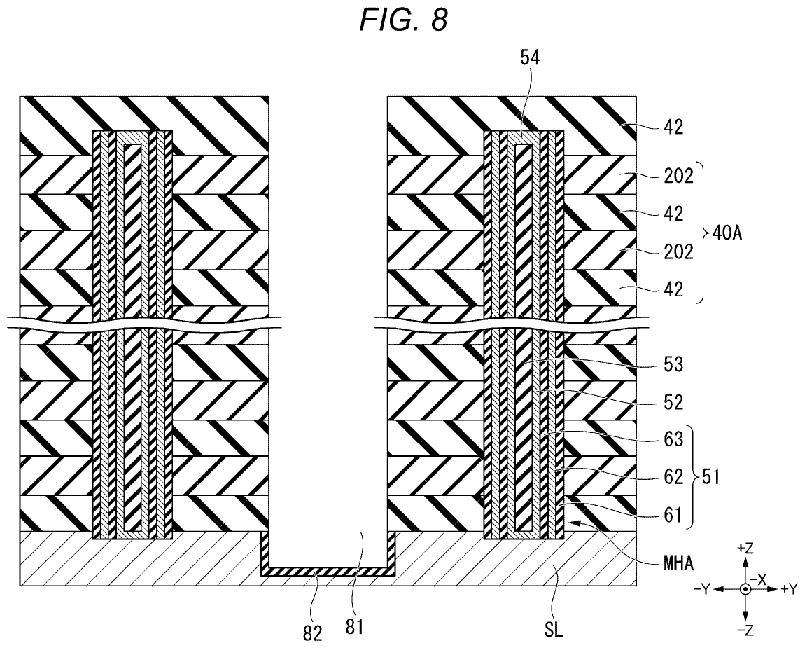

FIGS. 8 to 26 are cross-sectional views illustrating the method of manufacturing the semiconductor memory device 1 according to the first embodiment. The configuration illustrated in FIGS. 8 to 26 illustrates the cross-section of the region surrounded by the line F7 of the semiconductor memory device illustrated in FIG. 6 for convenience of description.

First, the source line SL is formed on the semiconductor substrate (not illustrated in FIG. 8) using, for example, a semiconductor material including silicon. Next, the insulating layer 42 is stacked on the source line SL, the insulating layer 202 and the insulating layer 42 are stacked thereon one by one alternately, and the insulating layer 42 is finally stacked. As a result, a stacked body 40A is formed. The insulating layer 202 is a sacrifice layer that is replaced with the conductive layer 41, for example, by executing a replacement step described below. The insulating layer 202 is formed of, for example, a film (for example, a silicon nitride film) including nitrogen and silicon. The insulating layer 202 is an example of “first layer”. The insulating layer 42 is an example of “second layer”.

Next, a columnar structure MHA that is the memory pillar MH is formed on the stacked body 40A. First, a plurality of holes for forming the memory pillars MH are formed. Each of the holes for forming the memory pillar MH penetrates the stacked body 40A in the Z direction. Next, for example, the tunnel insulating film 63 is formed along an inner wall of each of the holes. Next, for example, the charge trapping film 62 is formed along the inner wall of each of the holes where the tunnel insulating film 63 is formed. Next, for example, the block insulating film 61 is formed along the inner wall of each of the holes where the charge trapping film 62 is formed. As a result, the memory film 51 including the block insulating film 61, the charge trapping film 62, and the tunnel insulating film 63 is formed along the inner wall of each of the holes.

Next, the memory film 51 is removed by etching from a bottom surface of each of the holes where the memory film 51 is formed. By the etching using each of the holes where the memory film 51 is formed on the inner wall, the source line SL is exposed from the bottom surface of each of the holes.

Next, for example, the channel layer 52 is formed along the inner wall of each of the holes where the memory film 51 is formed. Next, for example, a material for r forming the insulating core 53 is supplied into each of the holes where the channel layer 52 is formed. As a result, the insulating core 53 is formed in each of the holes where the channel layer 52 is formed, and the columnar structure MHA that is the memory pillar MH is formed.

Next, the insulating core 53 disposed in an upper end portion of the columnar structure MHA is removed by etching. Next, the upper end portion of the columnar structure MHA is filled with, for example, amorphous silicon and is doped with impurity to form the cap portion 54.

Next, the insulating layer 42 is formed on a surface of the stacked body 40A opposite to the source line SL, the stacked body 40A having a structure where the columnar structure MHA that is the memory pillar MH is formed.

Next, the dividing portion ST is formed on the stacked body 40A. First, as illustrated in FIG. 8, by the etching from the surface of the stacked body 40A opposite to the source line SL, a groove 81 that penetrates the stacked body 40A in the Z direction, reaches the source line SL, and extends in the X direction is formed. Next, by oxidizing the source line SL exposed from the inside of the groove 81, a bottom oxide film 82 is formed.

Next, the replacement step of replacing the insulating layer 202 in the stacked body 40A with the conductive layer 41 is executed. First, the insulating layer 202 is removed by etching through the inside of the groove 81 where the bottom oxide film 82 is formed. As a result, a space 83 communicating with the groove 81 is formed in a region where the insulating layer 202 is present in the stacked body 40A.

Next, an insulating material for forming the insulating film 47 is supplied to the groove 81 where the insulating layer 202 is removed by etching, and the insulating film 47 is formed along an inner surface of the groove 81 where the insulating layer 202 is removed by etching and along an inner surface of the space 83 communicating with the groove 81.

Next, a metal material for forming the barrier metal film 46 is supplied to the groove 81 where the insulating film 47 is formed, and the barrier metal film 46 is formed along the inner surface of the groove 81 where the insulating film 47 is formed and along the inner surface of the space 83 communicating with the groove 81.

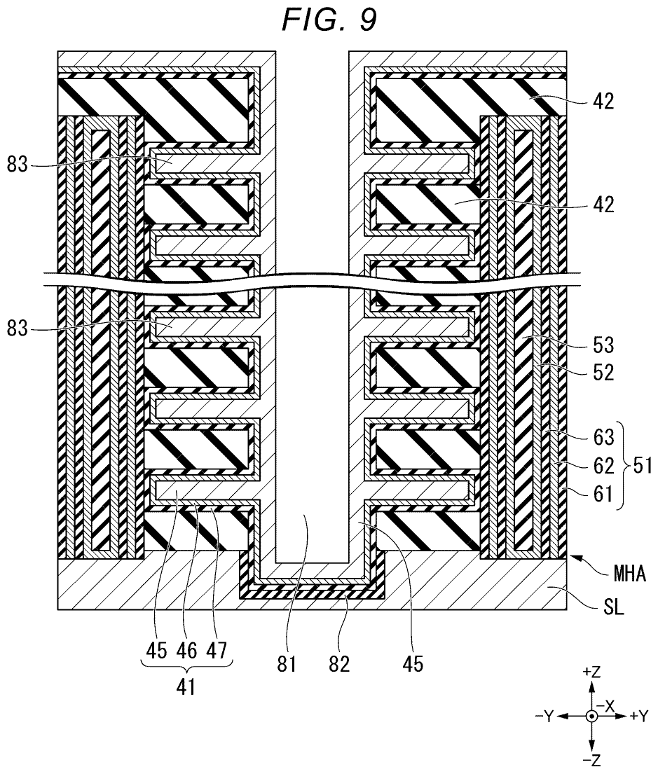

Next, a conductive material for forming the conductive portion 45 is supplied to the groove 81 where the barrier metal film 46 is formed. As a result, as illustrated in FIG. 9, the conductive portion 45 is formed along the inner surface of the groove 81 where the barrier metal film 46 is formed. Concurrently, the space 83 communicating with the groove 81 where the barrier metal film 46 is formed is embedded with the conductive portion 45, and the insulating layer 202 is replaced with the conductive layer 41 including the conductive portion 45, the barrier metal film 46, and the insulating film 47.

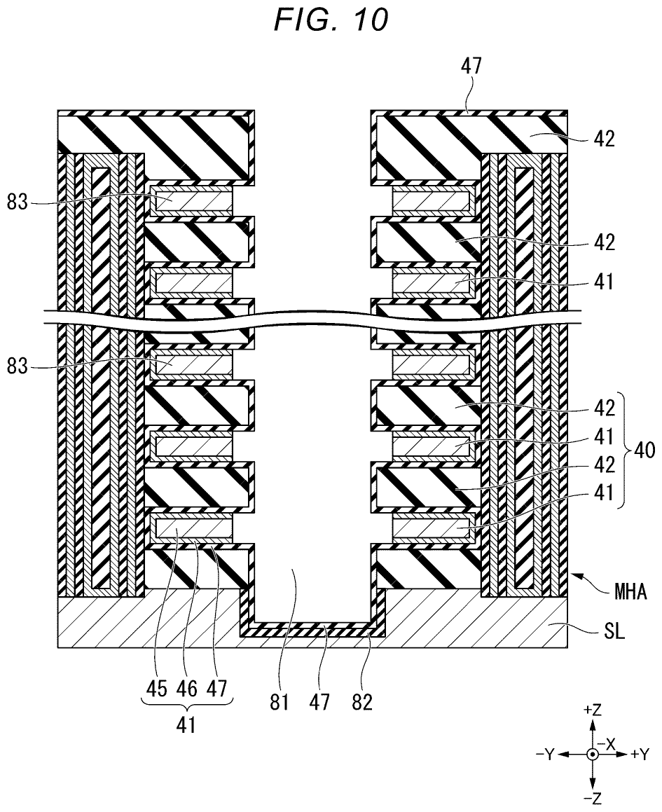

Next, as illustrated in FIG. 10, the conductive portion 45 and the barrier metal film 46 formed along the inner surface of the groove 81 are removed by etching through the groove 81 where the conductive layer 41 is formed. Concurrently, in the conductive portion 45 and the barrier metal film 46 formed in the space 83 communicating with the groove 81, one portion formed in a region close to the groove 81 is removed. As a result, the stacked body 40 where the plurality of conductive layers 41 and the plurality of insulating layers 42 are stacked one by one alternately in the Z direction is formed.

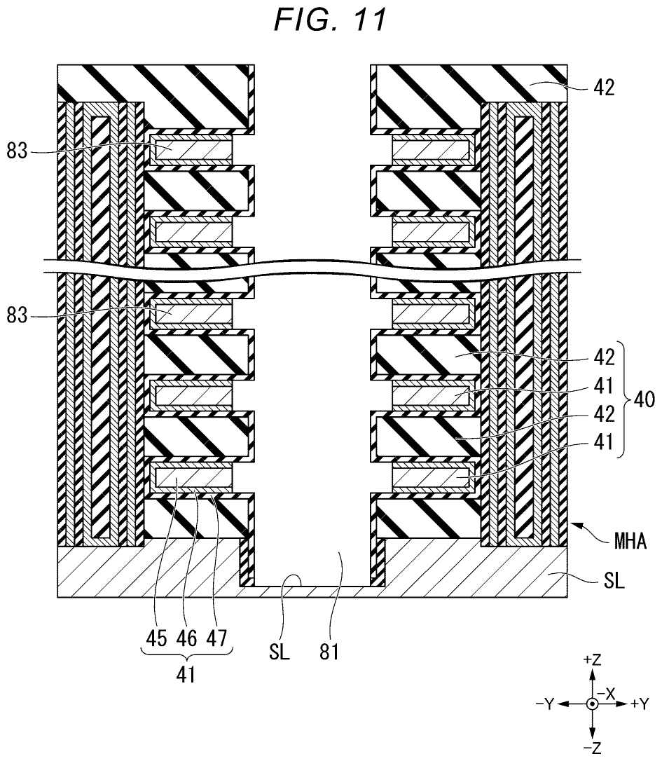

Next, as illustrated in FIG. 11, by etching the stacked body 40, the insulating film 47 exposed from the bottom surface of the groove 81 where the conductive portion 45 and the barrier metal film 46 are removed is removed together with the bottom oxide film 82 to expose the source line SL.

In the present embodiment, the case where the source line SL is exposed from the bottom surface of the groove 81 is described. In this case, the insulating film 47 and the bottom oxide film 82 do not need to be removed, or only the insulating film 47 may be removed.

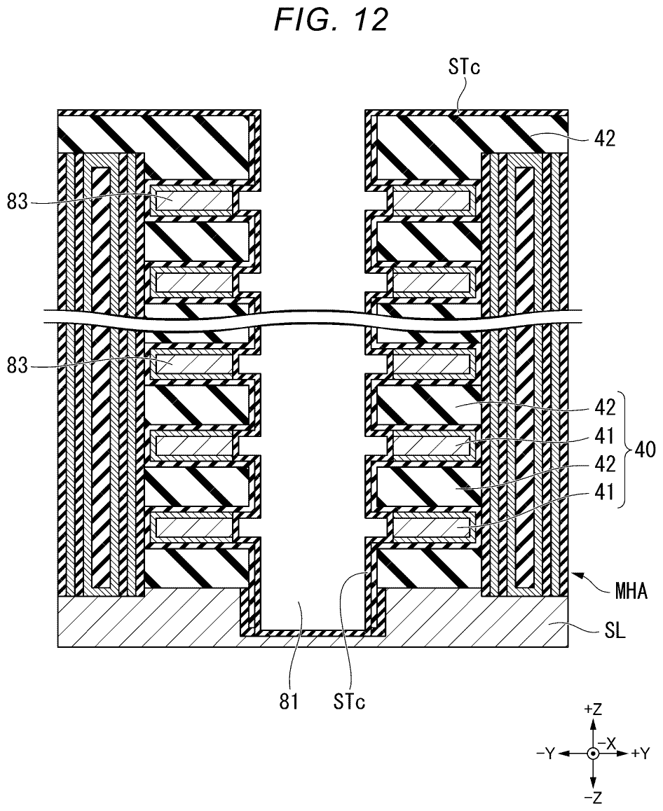

Next, as illustrated in FIG. 12, the source line SL is exposed from the bottom surface by etching, and an insulating material for forming the side wall insulating film STc is supplied to the groove 81 where an end portion of the conductive portion 45 on the groove 81 side is exposed from the space 83 communicating with the groove 81. Concurrently, the insulating material for forming the side wall insulating film STc is supplied to a surface on a side of the stacked body 40 opposite to the source line SL (first side of the stacked body 40 in the Z direction).

As a result, the side wall insulating film STc (first portion) extending in the Z direction and the X direction is formed along the inner surface of the groove 81 where the source line SL is exposed from the bottom surface by etching and along the inner surface of the space 83 communicating with the groove 81. Concurrently, the side wall insulating film STc (second portion) extending in the Y direction is formed along the surface of the stacked body 40 opposite to the source line SL from an opening portion of the groove 81 (end portion of the first portion on the first side in the Z direction). The side wall insulating film STc is an example of “third film”.

The side wall insulating film STc can be formed, for example, by chemical vapor deposition (CVD).

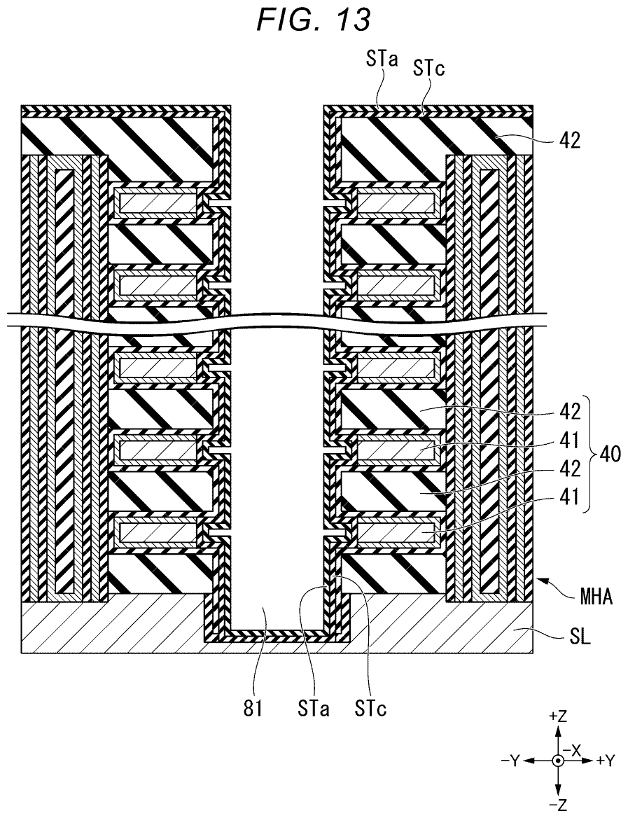

Next, as illustrated in FIG. 13, a material for forming the diffusion barrier layer STa is supplied to the groove 81 where the side wall insulating film STc is formed and to the surface of the stacked body 40 where the side wall insulating film STc is formed. As a result, the diffusion barrier layer STa (first portion) is formed along the inner surface of the groove 81 where the side wall insulating film STc is formed and along the inner surface of the space 83 communicating with the groove 81 where the side wall insulating film STc is formed. Concurrently, the diffusion barrier layer STa (second portion) extending in the Y direction is formed along the surface of the stacked body 40 opposite to the source line SL from the opening portion of the groove 81 (end portion of the first portion on the first side in the Z direction). The diffusion barrier layer STa is positioned on the side of the side wall insulating film STc opposite to the conductive layer 41 in the groove 81. The diffusion barrier layer STa is an example of “second film”.

The diffusion barrier layer STa can be formed, for example, by chemical vapor deposition (CVD).

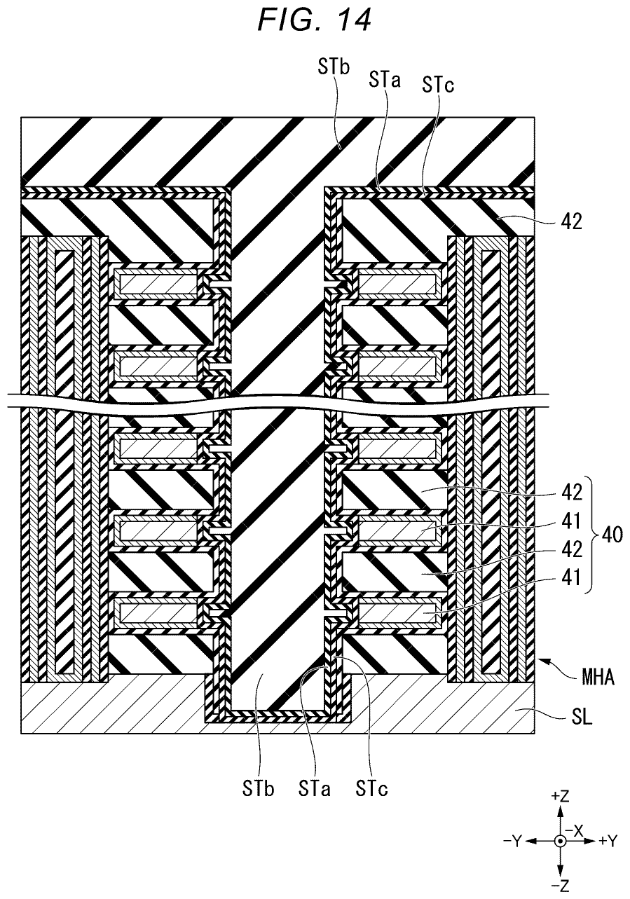

Next, as illustrated in FIG. 14, an insulating material for forming the embedded insulating film STb is supplied to the groove 81 where the diffusion barrier layer STa is formed and to the surface of the stacked body 40 where the side wall insulating film STc and the diffusion barrier layer STa are formed. As a result, the inside of the groove 81 where the diffusion barrier layer STa is formed and the inside of the space 83 communicating with the groove 81 are embedded with the embedded insulating 1 film STb. Concurrently, the embedded insulating film STb is formed on the surface of the stacked body 40 where the diffusion barrier layer STa is formed. The embedded insulating film STb is positioned on the side of the diffusion barrier layer STa opposite to the conductive layer 41 in the groove 81. The embedded insulating film STb is an example of “first film”.

The embedded insulating film STb can be formed, for example, by chemical vapor deposition (CVD) or a method of applying a liquid material such as polysilazane (PSZ) and annealing the applied liquid material.

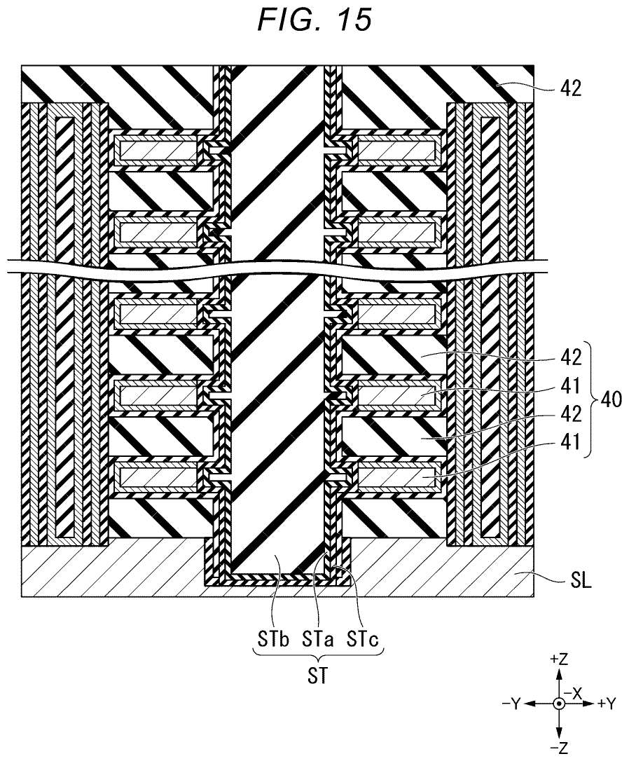

Next, as illustrated in FIG. 15, the surface of the stacked body 40 where the side wall insulating film STc, the diffusion barrier layer STa, and the embedded insulating film STb are formed is etched to expose the insulating layer 42 that forms the surface of the stacked body 40. As a result, the dividing portion ST including the embedded insulating film STb, the diffusion barrier layer STa, and the side wall insulating film STc is formed.

Next, a groove for providing the dividing portion SHE is formed in the stacked body 40, and the dividing portion SHE is formed in the groove.

Next, an insulating layer is stacked on the stacked body 40 where the dividing portion SHE is formed, and the contact CH is formed. Next, the contact VY is formed on the stacked body 40 where the contact CH is formed. Next, the bit line BL is formed above the contact VY. Next, the wiring portion 70 is formed.

Through the above-described steps, the second chip 3 is completed. The second chip 3 is bonded to the first chip 2 such that the wiring portion 70 side faces the first chip 2. As a result, the semiconductor memory device 1 according to the first embodiment is formed.

### 6.1 First Modification Example of Method of Manufacturing Semiconductor Memory Device

Next, a first modification example of the method of manufacturing the semiconductor memory device 1 according to the first embodiment will be described. A configuration other than steps described below is the same as the configuration of the method of manufacturing the semiconductor memory device 1 according to the above-described first embodiment.

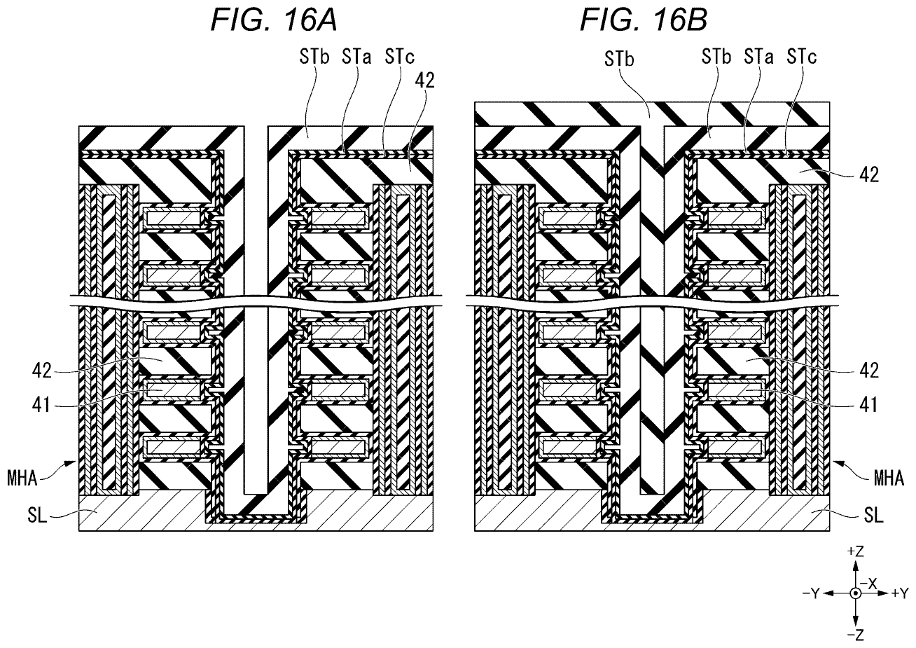

FIGS. 16A to 16B are cross-sectional views illustrating a first modification example of the method of manufacturing the semiconductor memory device according to the first embodiment.

In the first modification example of the method of manufacturing the semiconductor memory device 1 according to the first embodiment, the steps up to the formation of the diffusion barrier layer STa (refer to FIG. 13) along the inner surface of the groove 81 where the side wall insulating film STc is formed and the surface of the stacked body 40 where the side wall insulating film STc is formed (the surface of the stacked body 40 opposite to the source line SL) are executed using the same method as that of the method of manufacturing the semiconductor memory device 1 according to the first embodiment.

Next, in the first modification example, the step of forming the embedded insulating film STb is executed multiple times (for example, two times). When the step of forming the embedded insulating film STb is executed multiple times, the embedded insulating film STb may be formed using the same method every time, may be formed using different methods every time, or may be formed using the same method two times or more and subsequently formed using different methods.

When the step of forming the embedded insulating film STb is executed two times using different methods, for example, the embedded insulating film STb may be formed using the film forming method in the first step, and the embedded insulating film STb may be formed using the method of applying the liquid material in the second step.

In the first modification example, as illustrated in FIG. 16A, an insulating material for forming the embedded insulating film STb is supplied to the groove 81 where the diffusion barrier layer STa is formed and to the surface of the stacked body 40 where the side wall insulating film STc and the diffusion barrier layer STa are formed. At this time, as illustrated in FIG. 16A, the entirety of the inside of the groove 81 is not embedded with the embedded insulating film STb. That is, the embedded insulating film STb is formed along the inner surface of the groove 81 where the embedded insulating film STb is formed and along the surface of the stacked body 40 where the diffusion barrier layer STa is formed.

Next, as illustrated in FIG. 16B, an insulating material for forming the embedded insulating film STb is supplied to the groove 81 where the embedded insulating film STb is formed and to the surface of the stacked body 40 where the embedded insulating film STb is formed. As a result, the inside of the groove 81 where the diffusion barrier layer STa is formed is embedded with the embedded insulating film STb. Concurrently, the embedded insulating film STb is formed on the surface of the stacked body 40 where the diffusion barrier layer STa is formed.

In the present embodiment, the example where the step of forming the embedded insulating film STb is executed using the same material multiple times (for example, two times) is described. In this case, the step of forming the embedded insulating film STb may be executed using different materials every time, or may be executed using the same material some times.

Next, using the same method as the method of manufacturing the semiconductor memory device 1 according to the first embodiment, the surface of the stacked body 40 where the side wall insulating film STc, the diffusion barrier layer STa, and the embedded insulating film STb are formed is etched to expose the surface of the stacked body 40. As a result, the dividing portion ST including the embedded insulating film STb, the diffusion barrier layer STa, and the side wall insulating film STc is formed.

### 6.2 Second Modification Example of Method of Manufacturing Semiconductor Memory Device

Next, a second modification example of the method of manufacturing the semiconductor memory device 1 according to the first embodiment will be described. A configuration other than steps described below is the same as the configuration of the method of manufacturing the semiconductor memory device 1 according to the above-described first embodiment.

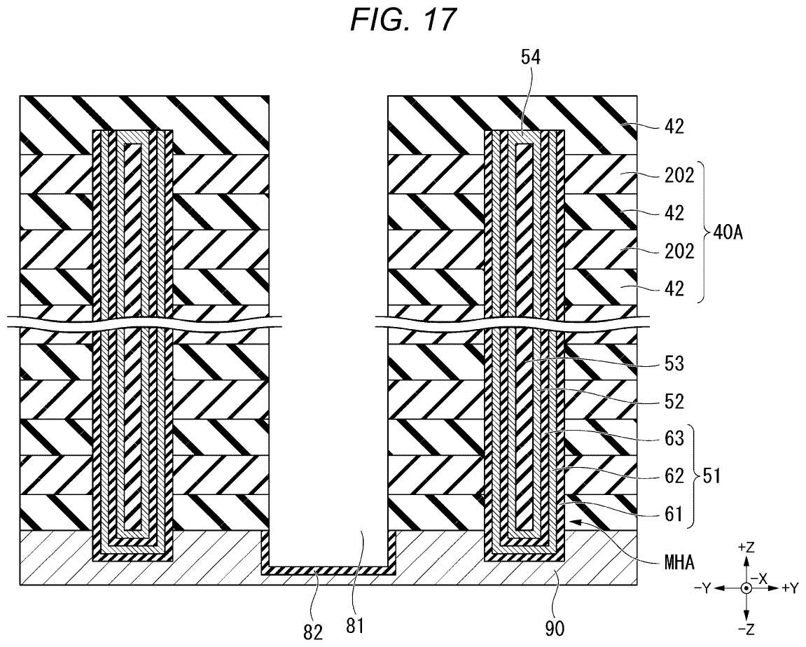

FIGS. 17 to 25 are cross-sectional views illustrating the second modification example of the method of manufacturing the semiconductor memory device 1 according to the first embodiment. The configuration illustrated in FIGS. 17 to 25 illustrates the cross-section of the region surrounded by the line F7 of the semiconductor memory device illustrated in FIG. 6 for convenience of description.

First, a sacrifice layer 90 is formed on the substrate (not illustrated in FIG. 17), for example, using polysilicon. Next, the insulating layer 42 is stacked on the sacrifice layer 90, the insulating layer 202 and the insulating layer 42 are stacked thereon one by one alternately, and the insulating layer 42 is finally stacked. As a result, a stacked body 40A is formed.

Next, a columnar structure MHA that is the memory pillar MH is formed on the stacked body 40A. First, a plurality of holes for forming the memory pillars MH are formed. Each of the holes for forming the memory pillar MH penetrates the stacked body 40A in the Z direction. Next, for example, the tunnel insulating film 63 is formed along an inner wall of each of the holes. Next, for example, the charge trapping film 62 is formed along the inner wall of each of the holes where the tunnel insulating film 63 is formed. Next, for example, the block insulating film 61 is formed along the inner wall of each of the holes where the charge trapping film 62 is formed. As a result, the memory film 51 including the block insulating film 61, the charge trapping film 62, and the tunnel insulating film 63 is formed along the inner wall of each of the holes.

Next, for example, the channel layer 52 is formed along the inner wall of each of the holes where the memory film 51 is formed. Next, for example, material for forming the insulating core 53 is supplied into each of the holes where the channel layer 52 is formed. As a result, the insulating core 53 is formed in each of the holes where the channel layer 52 is formed, and the columnar structure MHA that is the memory pillar MH is formed.

Next, the insulating core 53 disposed in an upper end portion of the columnar structure MHA is removed by etching. Next, the upper end portion of the columnar structure MHA is filled with, for example, amorphous silicon and is doped with impurity to form the cap portion 54.

Next, the insulating layer 42 is formed on a surface of the stacked body 40A opposite to the sacrifice layer 90, the stacked body 40A having a structure where the columnar structure MHA that is the memory pillar MH is formed.

Next, the dividing portion ST is formed on the stacked body 40A. First, as illustrated in FIG. 17, by the etching from the surface of the stacked body 40A opposite to the sacrifice layer 90, a groove 81 that penetrates the stacked body 40A in the Z direction, reaches the sacrifice layer 90, and extends in the X direction is formed. Next, by oxidizing the sacrifice layer 90 exposed from the inside of the groove 81, a bottom oxide film 82 is formed.

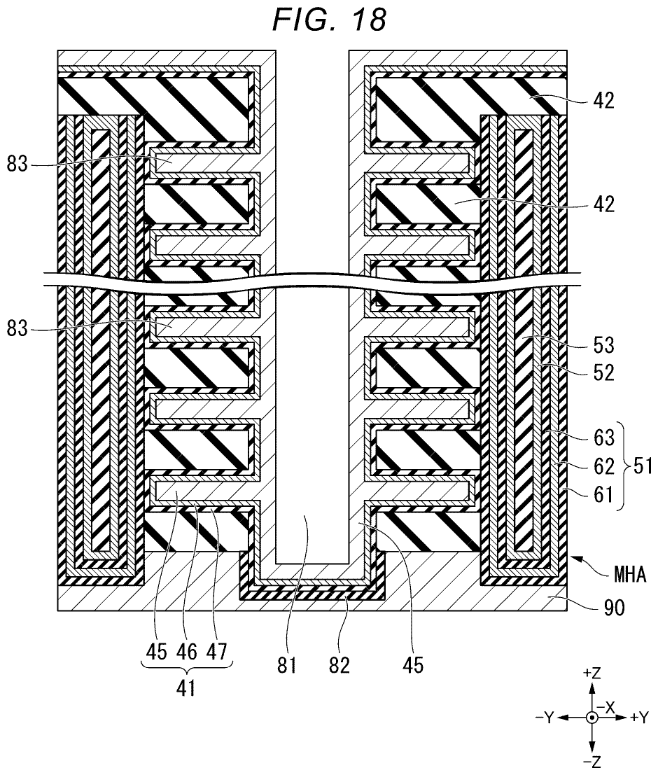

Next, the replacement step of replacing the insulating layer 202 in the stacked body 40A with the conductive layer 41 is executed. First, using the same method as the method of manufacturing the semiconductor memory device 1 according to the first embodiment, the insulating layer 202 is removed by etching, a space 83 communicating with the groove 81 is formed, and the insulating film 47 is formed along an inner surface of the groove 81 and along an inner surface of the space 83 communicating with the groove 81. Next, using the same method as the method of manufacturing the semiconductor memory device 1 according to the first embodiment, the barrier metal film 46 is formed along the inner surface of the groove 81 where the insulating film 47 is formed and along the inner surface of the space 83 communicating with the groove 81, and the conductive portion 45 is formed along the inner surface of the groove 81 where the barrier metal film 46 is formed. As a result, as illustrated in FIG. 18, the space 83 communicating with the groove 81 where the barrier metal film 46 is formed is embedded with the conductive portion 45. Concurrently, the insulating layer 202 is replaced with the conductive layer 41 including the conductive portion 45, the barrier metal film 46, and the insulating film 47.

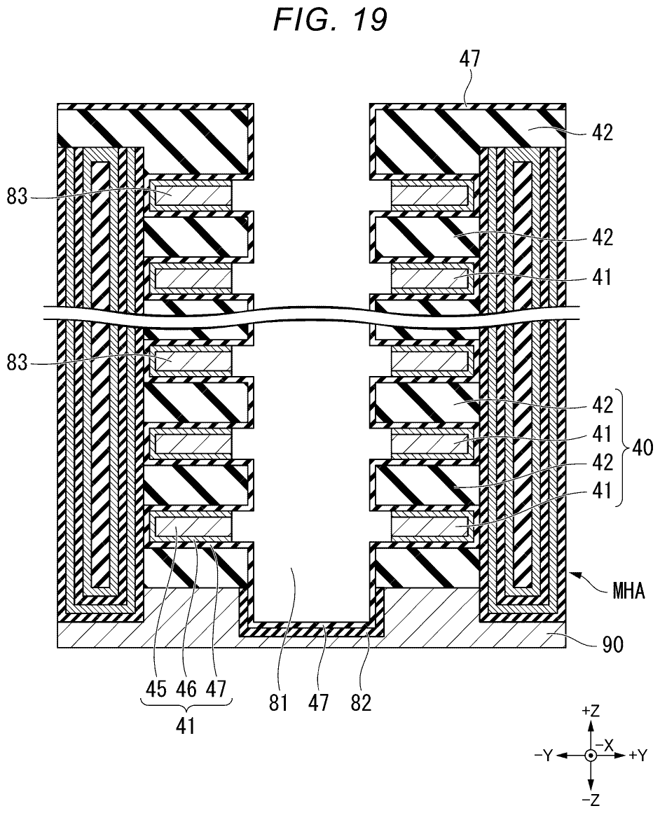

Next, using the same method as the method of manufacturing the semiconductor memory device 1 according to the first embodiment, as illustrated in FIG. 19, the conductive portion 45 and the barrier metal film 46 formed along the inner surface of the groove 81 are removed by etching through the groove 81 where the conductive layer 41 is formed.

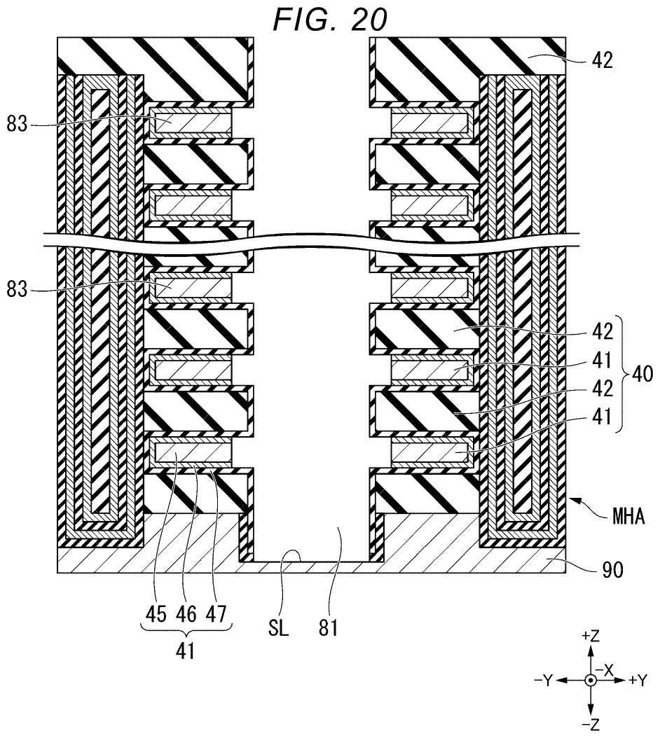

Next, using the same method as the method of manufacturing the semiconductor memory device 1 according to the first embodiment, as illustrated in FIG. 20, by etching the stacked body 40, the insulating film 47 exposed from the bottom surface of the groove 81 where the conductive portion 45 and the barrier metal film 46 are removed is removed together with the bottom oxide film 82 to expose the sacrifice layer 90.

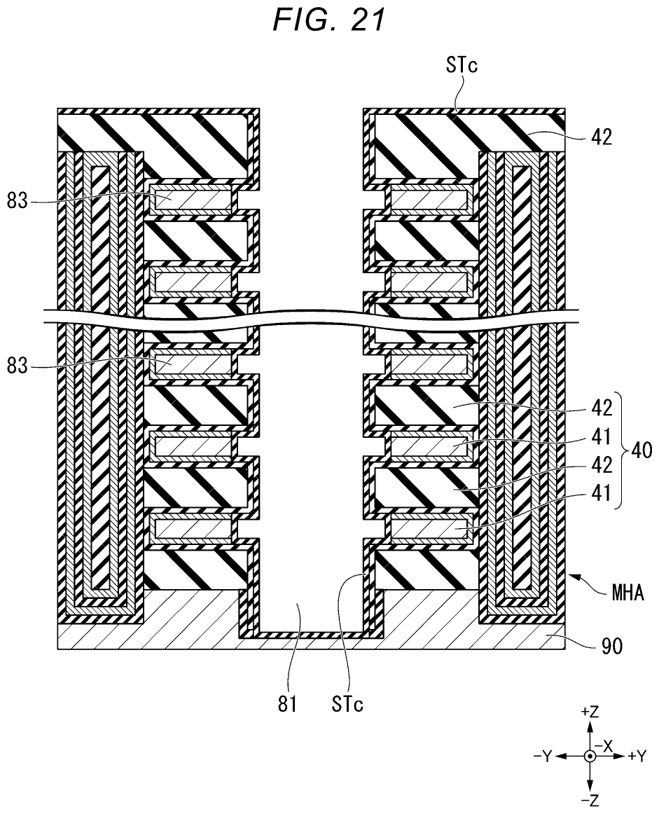

Next, using the same method as the method of manufacturing the semiconductor memory device 1 according to the first embodiment, as illustrated in FIG. 21, not only the side wall insulating film STc (first portion) extending in the Z direction and the X direction but also the side wall insulating film STC (second portion) extending in the Y direction are formed along the surface of the stacked body 40 opposite to the source line SL from an opening portion of the groove 81 (end portion of the first portion on the first side in the Z direction).

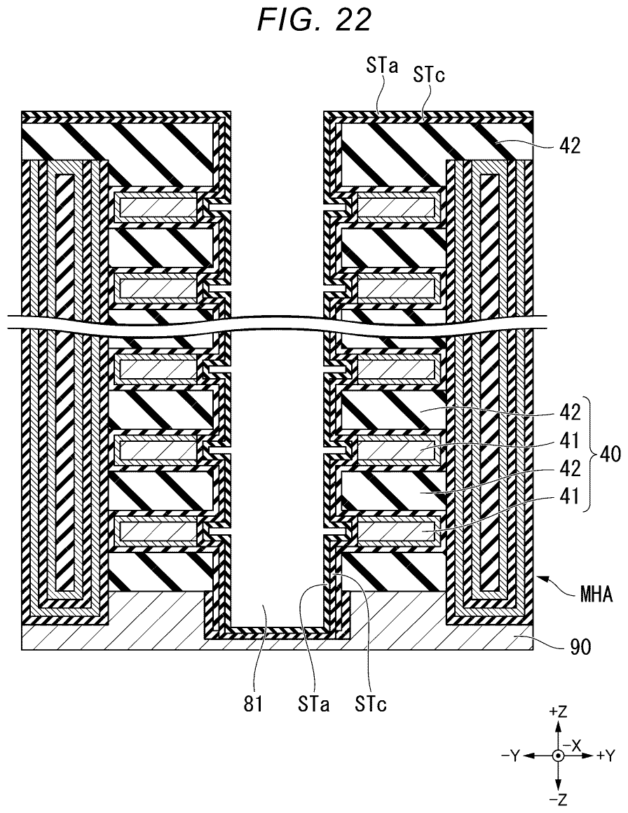

Next, using the same method as the method of manufacturing the semiconductor memory device 1 according to the first embodiment, as illustrated in FIG. 22, the diffusion barrier layer STa (first portion) is formed along the inner surface of the groove 81 where the side wall insulating film STc is formed and along the inner surface of the space 83 communicating with the groove 81 where the side wall insulating film STc is formed. Concurrently, the diffusion barrier layer STa (second portion) extending in the Y direction is formed along the surface of the stacked body 40 opposite to the source line SL from the opening portion of the groove 81 (end portion of the first portion on the first side in the Z direction).

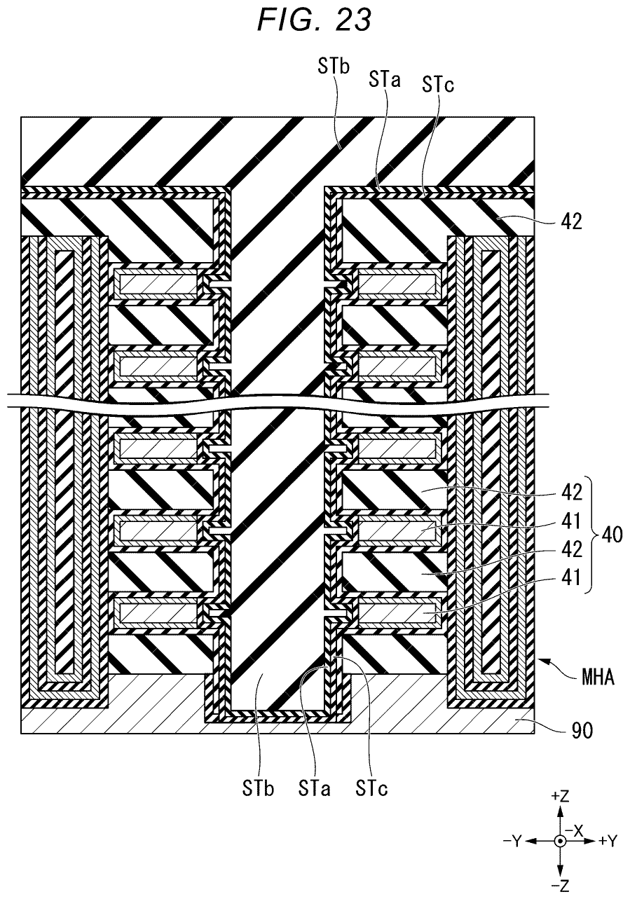

Next, using the same method as the method of manufacturing the semiconductor memory device 1 according to the first embodiment, as illustrated in FIG. 23, the inside of the groove 81 where the diffusion barrier layer STa is formed and the inside of the space 83 communicating with the groove 81 are embedded with the embedded insulating film STb. Concurrently, the embedded insulating film STb is formed on the surface of the stacked body 40 where the diffusion barrier layer STa is formed.

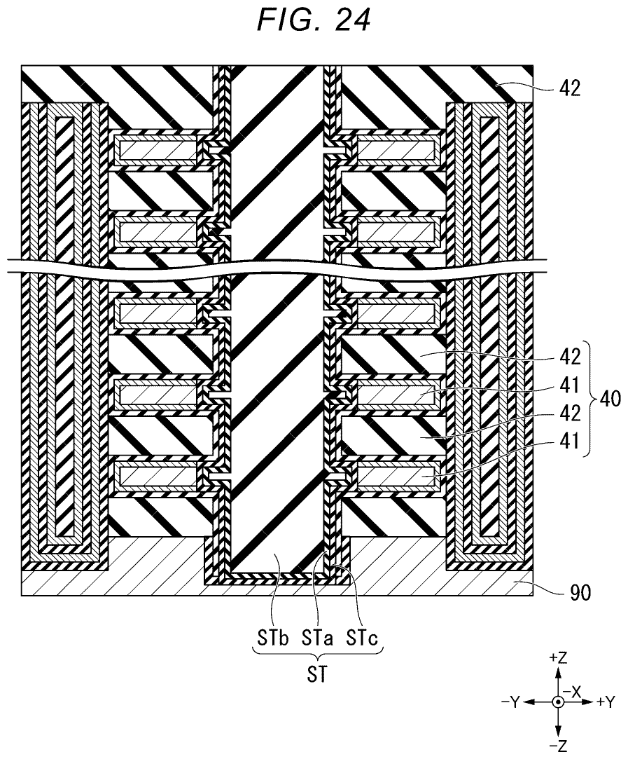

Next, using the same method as the method of manufacturing the semiconductor memory device 1 according to the first embodiment, as illustrated in FIG. 24, the insulating layer 42 that forms the surface of the stacked body 40 is exposed. As a result, the dividing portion ST including the embedded insulating film STb, the diffusion barrier layer STa, and the side wall insulating film STc is formed.

Next, using the same method as the method of manufacturing the semiconductor memory device 1 according to the first embodiment, the dividing portion SHE, the contact CH, the contact VY, the bit line BL, and the wiring portion 70 are formed.

Through the above-described steps, the second chip 3 is completed. Next, the second chip 3 and the first chip 2 are bonded such that the wiring portion 70 side of the second chip 3 faces the first chip 2.

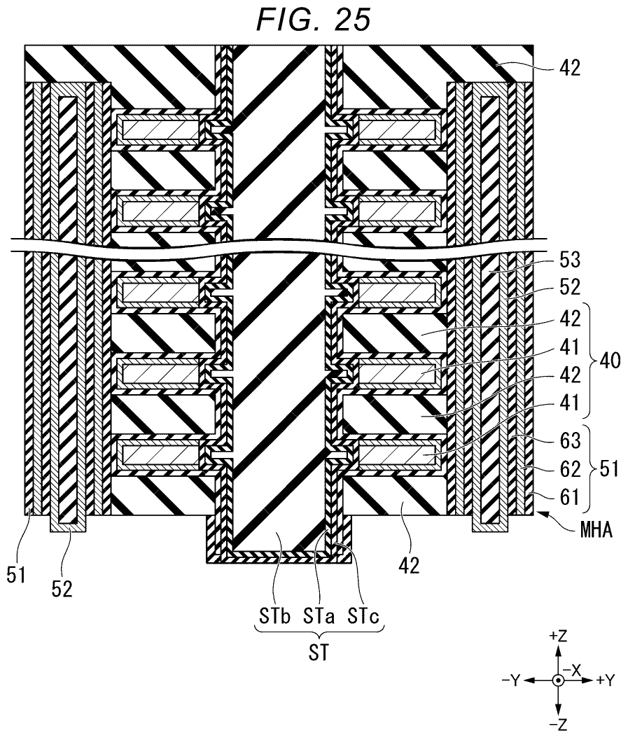

Next, the substrate of the second chip 3 is peeled off from the surface of the second chip 3 opposite to the side where the first chip 2 is bonded, and the sacrifice layer 90 is removed by etching. As a result, the insulating layer 42 and the memory film 51 of the columnar structure MHA are exposed from the surface (lower surface in FIG. 25) of the stacked body 40 opposite to the first chip 2 (not illustrated in FIG. 25). As a result, the memory film 51 is removed by etching, and the channel layer 52 of the columnar structure MHA is exposed as illustrated in FIG. 25.

Next, the source line SL is formed on the insulating layer 42 exposed from the surface of the stacked body 40 opposite to the first chip 2 and on the channel layer 52 of the columnar structure MHA, for example, using a semiconductor material including silicon.

As a result, the semiconductor memory device 1 according to the first embodiment is formed.

### 6.3 Third Modification Example of Method of Manufacturing Semiconductor Memory Device

Next, a third modification example of the method of manufacturing the semiconductor memory device 1 according to the first embodiment will be described. A configuration other than steps described below is the same as the configuration of the method of manufacturing the semiconductor memory device 1 according to the above-described first embodiment.

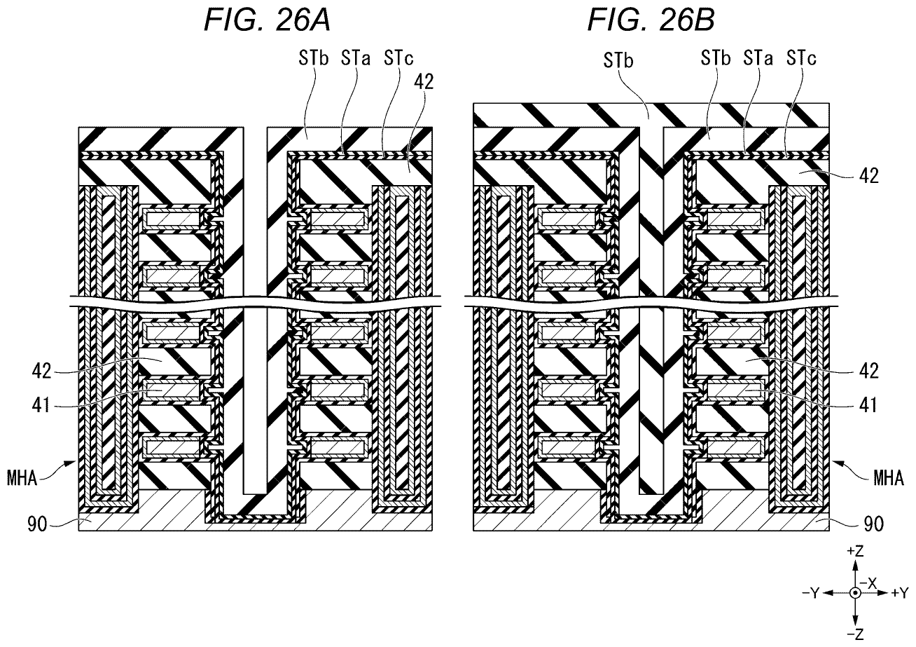

FIGS. 26A and 26B are cross-sectional views illustrating the third modification example of the method of manufacturing the semiconductor memory device according to the first embodiment.

In the third modification example of the method of manufacturing the semiconductor memory device 1 according to the first embodiment, the steps up to the formation of the diffusion barrier layer STa (refer to FIG. 22) along the inner surface of the groove 81 where the side wall insulating film STc is formed and the surface of the stacked body 40 where the side wall insulating film STc is formed (the surface of the stacked body 40 opposite to the sacrifice layer 90) are executed using the same method as that of the second modification example of the method of manufacturing the semiconductor memory device 1 according to the first embodiment.

Next, in the third modification example, as in the first modification example, the step of forming the embedded insulating film STb is executed multiple times (for example, two times) (refer to FIGS. 26A and 26B).

Next, in the third modification example, using the same method as the second modification example of the method of manufacturing the semiconductor memory device 1 according to the first embodiment, the surface of the stacked body 40 where the side wall insulating film STc, the diffusion barrier layer STa, and the embedded insulating film STb are formed is etched to expose the surface of the stacked body 40. As a result, the dividing portion ST including the embedded insulating film STb, the diffusion barrier layer STa, and the side wall insulating film STc is formed.

### 7. Advantageous Effects

The semiconductor memory device 1 according to the first embodiment includes the stacked body 40 and the dividing portion ST. The stacked body 40 includes the plurality of conductive layers 41 and the plurality of insulating layers 42 and where the plurality of conductive layers 41 and the plurality of insulating layers 42 are stacked one by one alternately in the Z direction. The dividing portion ST penetrates the stacked body 40 and extends in the Z direction and the X direction. The dividing portion ST includes the embedded insulating film STb and the diffusion barrier layer STa. The embedded insulating film STb extends in the Z direction and the X direction and has insulating characteristics. The diffusion barrier layer STa is positioned between the conductive layer 41 and the embedded insulating film STb in the Y direction, extends in the Z direction and the X direction, has a smaller thickness in the Y direction than the embedded insulating film STb, and includes a material different from that of the embedded insulating film STb.

Accordingly, in the semiconductor memory device 1 according to the first embodiment, the diffusion barrier layer STa positioned between the conductive layer 41 and the embedded insulating film STb in the Y direction can prevent the impurity in the embedded insulating film STb having a larger thickness in the Y direction than the diffusion barrier layer STa from being diffused to the conductive layer 41. As a result, reliability of the memory cell array 11 can be improved, and electrical characteristics of the semiconductor memory device 1 can be improved.

In particular, when the embedded insulating film STb is formed using the method of applying the liquid material such as polysilazane (PSZ) and annealing the applied liquid material, the impurity in the embedded insulating film STb is likely to be diffused to the conductive layer 41. Therefore, the effect of the diffusion barrier layer STa preventing the impurity in the embedded insulating film STb from being diffused to the conductive layer 41 is significant.

### 8. Modification Example of Semiconductor Memory Device

Next, modification examples of the semiconductor memory device 1 according to the first embodiment will be described. A configuration other than a configuration described below is the same as the configuration of the manufacturing method according to the above-described first embodiment.

### 8.1 First Modification Example of Semiconductor Memory Device

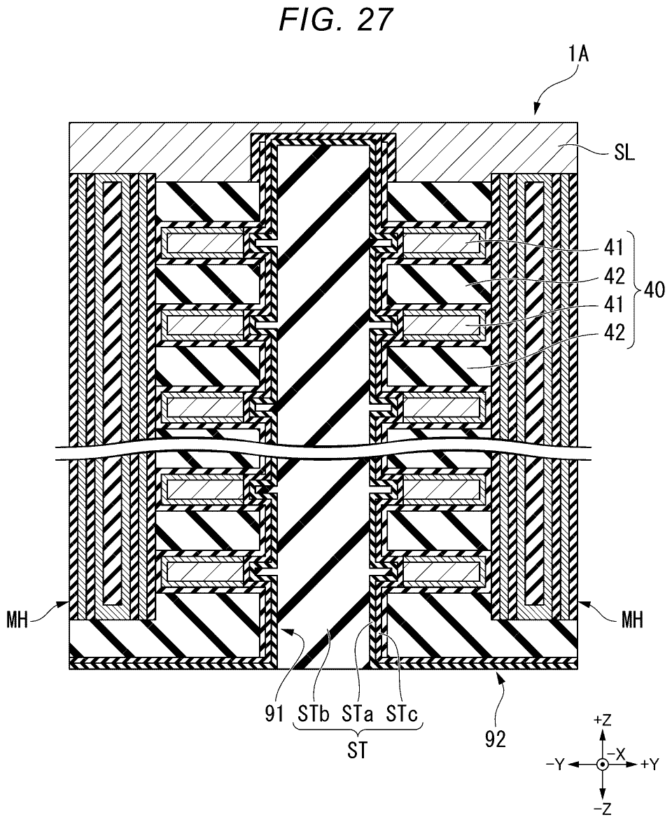

FIG. 27 is a cross-sectional view illustrating a first modification example of the semiconductor memory device according to the first embodiment. FIG. 27 is an enlarged cross-sectional view illustrating a region corresponding to the region surrounded by the line F7 illustrated in FIG. 6 in the semiconductor memory device 1 according to the first embodiment.

In the dividing portion ST of a semiconductor memory device 1A according to the first modification example, unlike the semiconductor memory device 1 according to the first embodiment, the side wall insulating film STc and the diffusion barrier layer STa include not only a first portion 91 extending in the Z direction and the X direction in the dividing portion ST but also a second portion 92 extending in the Y direction from an end portion of the first side (in FIG. 27, the lower side) of the first portion 91 in the Z direction. The second portion 92 of the side wall insulating film STc and the diffusion barrier layer STa is disposed between the stacked body 40 and a plurality of wirings. The plurality of wirings are wirings disposed on the first side of the stacked body 40 in the Z direction and includes, for example, the bit line BL and the wirings 71 and 72 (refer to FIG. 6).

The semiconductor memory device 1A illustrated in FIG. 27 can be formed, for example, using the following method.

That is, using the same method as the method of manufacturing the semiconductor memory device 1 according to the first embodiment, the inside of the groove 81 where the side wall insulating film STc and the diffusion barrier layer STa are formed and the inside of the space 83 communicating with the groove 81 are embedded with the embedded insulating film STb. Concurrently, the steps up to the formation of the embedded insulating film STb (refer to FIG. 14) on the surface of the stacked body 40 where the side wall insulating film STc and the diffusion barrier layer STa are formed are executed.

Next, the surface of the stacked body 40 where the side wall insulating film STc, the diffusion barrier layer STa, and the embedded insulating film STb are formed is etched to expose the surface of the diffusion barrier layer STa. As a result, the side wall insulating film STc and the diffusion barrier layer STa that include the first portion 91 extending in the Z direction and the X direction in the dividing portion ST and the second portion 92 extending in the Y direction from the end portion of the first side (in FIG. 27, the lower side) of the first portion 91 in the Z direction are formed.

In the semiconductor memory device 1A illustrated in FIG. 27, when a wiring is disposed on the first side (the lower side in FIG. 27) of the stacked body 40 in the Z direction, the contact CH and the contact CC to be connected to the wiring are formed before forming the wiring. The contact CH and the contact CC are formed after executing the step of removing by etching formation regions of the contact CH and the contact CC in the X direction and the Y direction and the vicinity thereof in the second portion 92 of the side wall insulating film STc and the diffusion barrier layer STa.

In the dividing portion ST of the semiconductor memory device 1A according to the first modification example, the side wall insulating film STc and the diffusion barrier layer STa include the second portion 92 extending in the Y direction from the end portion of the first side (in FIG. 27, the lower side) of the first portion 91 in the Z direction. Therefore, for example, in the step of forming the bit line BL and the wiring 71, impurity can be prevented from being diffused to the conductive layer 41 from the first side of the first portion 91 in the Z direction.

### 8.2 Second Modification Example of Semiconductor Memory Device

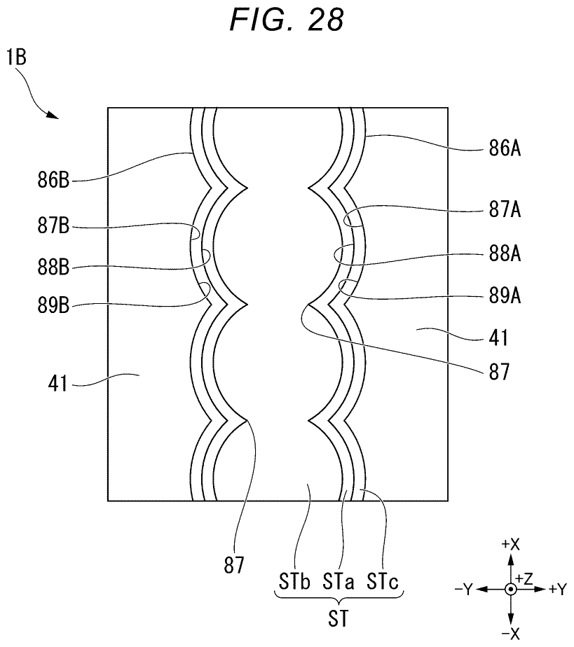

FIG. 28 is a plan view illustrating a second modification example of the semiconductor memory device according to the first embodiment. FIG. 28 does not illustrate the insulating film 47 in the conductive layer 41, and illustrates conductive portion 45 and the barrier metal film 46 that are integrated as the conductive layer 41.

As in the dividing portion ST of the semiconductor memory device 1 according to the first embodiment, the dividing portion ST of a semiconductor memory device 1B according to the second modification example includes the embedded insulating film STb, the diffusion barrier layer STa, and the side wall insulating film STc.

When seen from the Z direction, the dividing portion ST of the semiconductor memory device 1B according to the second modification example includes a first end portion 86A positioned on a first side (in FIG. 28, the right side) in the Y direction and a second end portion 86B positioned on a second side (in FIG. 28, the left side) in the Y direction opposite to the first side.

The first end portion 86A includes a plurality of first arc portions 87A each of which has a convex shape toward an outer side of the dividing portion ST in the Y direction and that are adjacent to each other in the X direction. In addition, the second end portion 86B includes a plurality of second arc portions 87B each of which has a convex shape toward an outer side of the dividing portion ST in the Y direction and that are adjacent to each other in the X direction.

As illustrated in FIG. 28, the diffusion barrier layer STa includes a plurality of third arc portions 88A along the plurality of first arc portions 87A and a plurality of fourth arc portions 88B along the plurality of second arc portions 87B. The side wall insulating film STc includes a plurality of fifth arc portions 89A along the plurality of first arc portions 87A and a plurality of sixth arc portions 89B along the plurality of second arc portions 87B.

In the semiconductor memory device 1B according to the second modification example, the dividing portion ST includes the plurality of first arc portions 87A and the plurality of second arc portions 87B. Therefore, an electric field is likely to concentrate on a portion 87 that is formed between the first arc portions 87A adjacent to each other and between the second arc portions 87B adjacent to each other and protrudes in a pointed shape toward the inside of the dividing portion ST in the Y direction. In the second modification example, the diffusion barrier layer STa includes the plurality of third arc portions 88A and the plurality of fourth arc portions 88B. Therefore, when the diffusion barrier layer STa is formed of a material having a relatively higher dielectric constant than that of the material of the embedded insulating film STb and the side wall insulating film STC, the electric field concentration on the portion 87 that protrudes in the above-described pointed shape can be alleviated.

In the semiconductor memory device 1B according to the second modification example, when the embedded insulating film STb and the side wall insulating film STc are formed of, for example, a film including silicon and oxygen, it is preferable that the diffusion barrier layer STa is formed of, for example, a material including silicon and nitrogen or a material including oxygen and one or more selected from among aluminum, hafnium, and zirconium.

In the semiconductor memory device 1B according to the second modification example, a groove for forming the dividing portion ST can be formed, for example, while forming the plurality of holes for forming the memory pillars MH and/or while forming the plurality of holes for forming the contacts CC. In this case, independently of the step of forming the holes for forming the memory pillars MH and the step of forming the plurality of holes for forming the contacts CC, the dividing portion ST can be formed more efficiently as compared to a case where the step of forming only the groove for forming the dividing portion ST is provided.

### 8.3 Third Modification Example of Semiconductor Memory Device

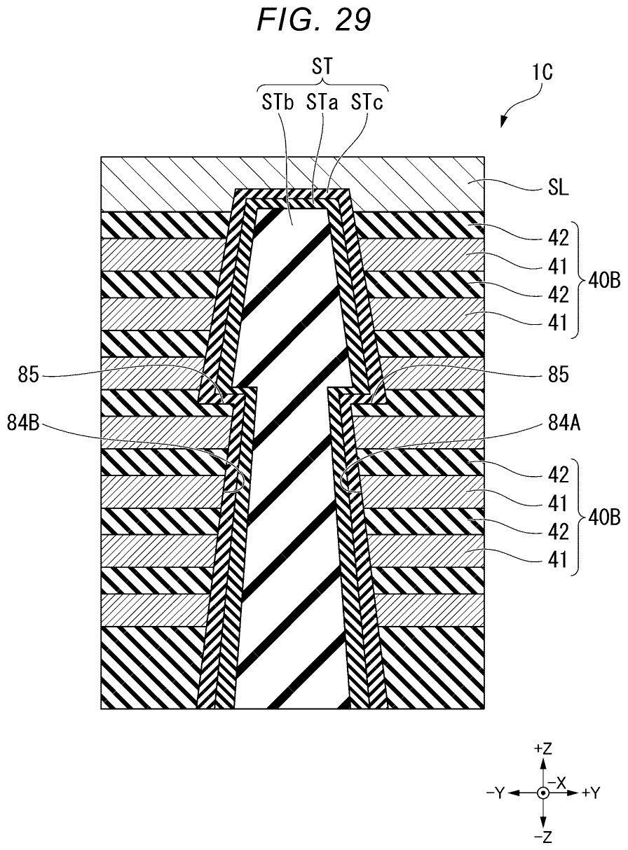

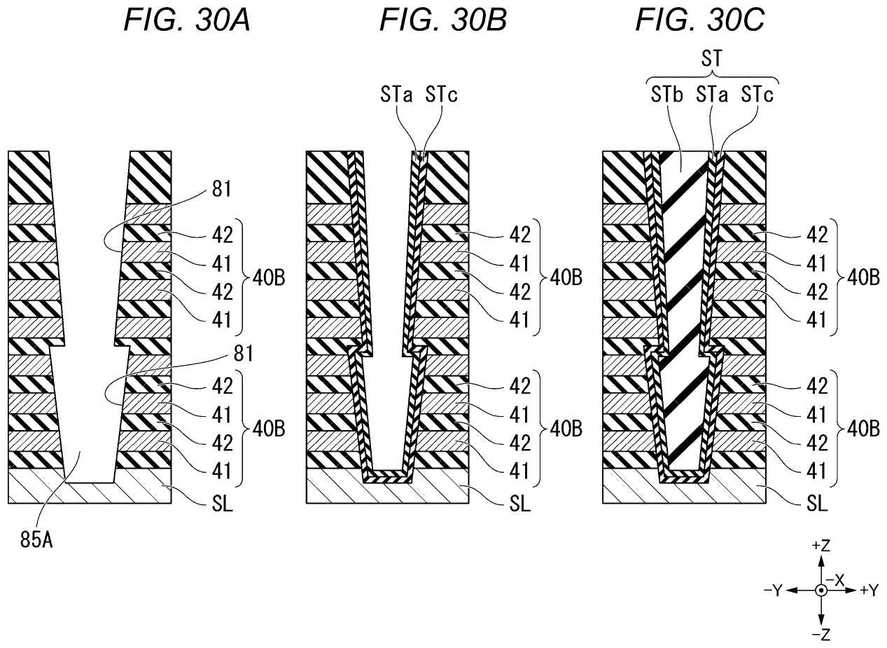

FIG. 29 is a cross-sectional view illustrating a third modification example of the semiconductor memory device according to the first embodiment. FIG. 29 is a diagram illustrating a portion of a semiconductor memory device 1C according to the third modification example different from that of the semiconductor memory device 1 according to the first embodiment. FIGS. 30A to 30C are cross-sectional views illustrating the method of manufacturing the semiconductor memory device illustrated in FIG. 29. FIGS. 29 and 30 do not illustrate the insulating film 47 in the conductive layer 41, and illustrate the conductive portion 45 and the barrier metal film 46 that form the conductive layer 41 and are integrated as the conductive layer 41. In addition, FIGS. 29 and 30 do not illustrate the dividing portion ST that is embedded in a region where the conductive layer 41 is not present between the insulating layer 42 and the insulating layer 42.

As in the dividing portion ST of the semiconductor memory device 1 according to the first embodiment, the dividing portion ST of the semiconductor memory device 1C according to the third modification example includes the embedded insulating film STb, the diffusion barrier layer STa, and the side wall insulating film STc.

As illustrated in FIG. 29, when seen from the X direction, the dividing portion ST of the semiconductor memory device 1C according to the third modification example includes a first end portion 84A positioned on a first side (in FIG. 29, the right side) in the Y direction and a second end portion 84B positioned on a second side (in FIG. 29, the left side) in the Y direction opposite to the first side. Unlike the first embodiment, in the dividing portion ST in the semiconductor memory device 1C according to the third modification example, the first end portion 84A and the second end portion 84B include a portion 85 extending in the Y direction.

As illustrated in FIG. 29, the semiconductor memory device 1C according to the third modification example has a structure where two stacked bodies 40B are stacked, the stacked body 40B having the structure where the plurality of conductive layers 41 and the plurality of insulating layers 42 are stacked one by one alternately in the Z direction, the outermost layer is the insulating layer 42, and the columnar structure MHA (not illustrated in FIG. 29) that is the memory pillar MH is provided. The portion 85 in the first end portion 84A and the second end portion 84B extending in the Y direction is a level difference that is formed by stacking the two stacked bodies 40B where the groove for forming the dividing portion ST is formed.

The semiconductor memory device 1C according to the third modification example can be formed, for example, using the following method.

That is, using the same method as the method of manufacturing the semiconductor memory device 1 according to the first embodiment, the steps up to the step of removing the insulating film 47 exposed from the bottom surface of the groove 81 where the conductive portion 45 and the barrier metal film 46 are removed by etching together with the bottom oxide film 82 to expose the source line SL (refer to FIG. 11) are executed. As a result, the first stacked body 40B is formed.

In addition, using the same method as the method of manufacturing the semiconductor memory device 1 according to the first embodiment except that the source line SL is not formed, after executing the steps up to the step of removing the insulating film 47 exposed from the bottom surface of the groove 81 where the conductive portion 45 and the barrier metal film 46 are removed by etching (refer to FIG. 11), the semiconductor substrate (not illustrated in FIG. 11) is removed to form the second stacked body 40B where the groove 81 penetrates in the Z direction.

Next, as illustrated in FIG. 30A, the first stacked body 40B and the second stacked body 40B are stacked such that a part or the entirety of the groove 81 of the first stacked body 40B and the groove 81 of the second stacked body 40B overlap each other when seen from the Z direction. As a result, the groove 81 of the first stacked body 40B and the groove 81 of the second stacked body 40B are connected in the Z direction to form a groove 85A.

Next, using the same method as the method of manufacturing the semiconductor memory device 1 according to the first embodiment, the side wall insulating film STc extending in the Z direction and the X direction along an inner surface and a bottom surface of the groove 85A and the diffusion barrier layer STa are formed in this order (refer to FIG. 30B).

Next, as illustrated in FIG. 30C, an insulating material is supplied to the groove 85A where the side wall insulating film STc and the diffusion barrier layer STa are formed. As a result, the inside of the groove 85A where the side wall insulating film STc and the diffusion barrier layer STa are formed is embedded with the embedded insulating film STb.

The embedded insulating film STb in the semiconductor memory device 1C according to the third modification example can be formed, for example, by chemical vapor deposition (CVD) or a method of applying a liquid material such as polysilazane (PSZ) and annealing the applied liquid material. The method of applying a liquid material such as polysilazane (PSZ) and annealing the applied liquid material is preferable because it is a method in which excellent embeddability can be obtained even when the groove 85A (refer to FIG. 30A) obtained by connecting the groove 81 of the first stacked body 40B and the groove 81 of the second stacked body 40B in the Z direction has a narrow width in the Y direction and is deep in the Z direction.

When the embedded insulating film STb in the semiconductor memory device 1C according to the third modification example is formed using the method of applying the liquid material such as polysilazane (PSZ) and annealing the applied liquid material, the impurity in the embedded insulating film STb is likely to be diffused to the conductive layer 41. However, in the semiconductor memory device 1C according to the third modification example, the dividing portion ST includes the diffusion barrier layer STa. Therefore, by applying a liquid material such as polysilazane (PSZ) and annealing the applied liquid material, the impurity in the embedded insulating film STb can be prevented from being diffused to the conductive layer 41.

### 8.4 Fourth Modification Example of Semiconductor Memory Device

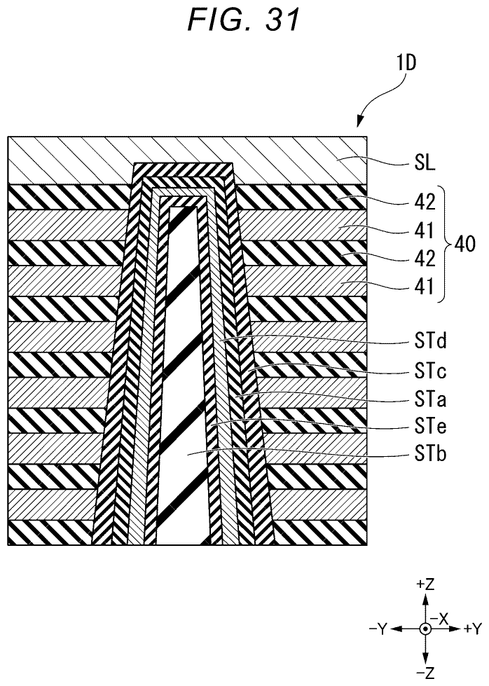

FIG. 31 is a cross-sectional view illustrating a fourth modification example of the semiconductor memory device according to the first embodiment. FIG. 31 is a diagram illustrating a portion of a semiconductor memory device 1D according to the fourth modification example different from that of the semiconductor memory device 1 according to the first embodiment. FIG. 31 does not illustrate the insulating film 47 in the conductive layer 41, and illustrates the conductive portion 45 and the barrier metal film 46 that form the conductive layer 41 and are integrated as the conductive layer 41. In addition, FIG. 31 does not illustrate the dividing portion ST that is embedded in a region where the conductive layer 41 is not present between the insulating layer 42 and the insulating layer 42.

As in the dividing portion ST of the semiconductor memory device 1 according to the first embodiment, the dividing portion ST of the semiconductor memory device 1D according to the fourth modification example includes the embedded insulating film STb, the diffusion barrier layer STa, and the side wall insulating film STc.

As illustrated in FIG. 31, the dividing portion ST in the semiconductor memory device 1D according to the fourth modification example includes a second embedded insulating film STd that is positioned between the embedded insulating film STb and the diffusion barrier layer STa in the Y direction, extends in the Z direction and the X direction, and includes a material different from that of the diffusion barrier layer STa. The second embedded insulating film STd is an example of “fourth film”.

As the material of the second embedded insulating film STd, a material that can be used for the above-described embedded insulating film STb can be used. In the semiconductor memory device 1D according to the fourth modification example, the second embedded insulating film STd and the embedded insulating film STb may be formed of the same material or different materials.

Further, the dividing portion ST in the semiconductor memory device 1D according to the fourth modification example includes a second diffusion barrier layer STe that is positioned between the embedded insulating film STb and the second embedded insulating film STd in the Y direction, extends in the Z direction and the X direction, and includes a material different from those of the embedded insulating film STb and the second embedded insulating film STd. The second diffusion barrier layer STe is an example of “fifth film”.

As the material of the second diffusion barrier layer STe, a material that can be used for the above-described diffusion barrier layer STa can be used. In the semiconductor memory device 1D according to the fourth modification example, the second diffusion barrier layer STe and the diffusion barrier layer STa may be formed of the same material or different materials. When the second diffusion barrier layer STe and the diffusion barrier layer STa are formed of different materials, the second diffusion barrier layer STe and the diffusion barrier layer STa can prevent plural kinds of impurities from being diffused from the embedded insulating film STb to the conductive layer 41.

The dividing portion ST in the semiconductor memory device 1D according to the fourth modification example can be formed, for example, using the following method.

That is, using the same method as the method of forming the embedded insulating film STb in the method of manufacturing the semiconductor memory device 1 according to the first embodiment, the second embedded insulating film STd can be formed along the inner surface of the groove 81 where the diffusion barrier layer STa is formed and along the surface of the stacked body 40 where the side wall insulating film STc and the diffusion barrier layer STa are formed (the surface of the stacked body 40 opposite to the source line SL) (refer to FIG. 16A).

Next, using the same method as the method of forming the diffusion barrier layer STa in the method of manufacturing the semiconductor memory device 1 according to the first embodiment, the second diffusion barrier layer STe extending in the Z direction and the X direction is formed along the inner surface of the groove 81.

Next, using the same method as the method of forming the embedded insulating film STb in the first modification example of the method of manufacturing the semiconductor memory device, the inside of the groove 81 where the second diffusion barrier layer STe is formed is embedded with the embedded insulating film STb.

The semiconductor memory device 1D according to the fourth modification example includes the diffusion barrier layer STa and the second diffusion barrier layer STe. Therefore, the impurity in the embedded insulating film STb and the second diffusion barrier layer STe can be prevented from being diffused to the conductive layer 41. As a result, reliability of the memory cell array 11 can be improved, and electrical characteristics of the semiconductor memory device 1 can be improved.

### 8.5 Fifth Modification Example of Semiconductor Memory Device

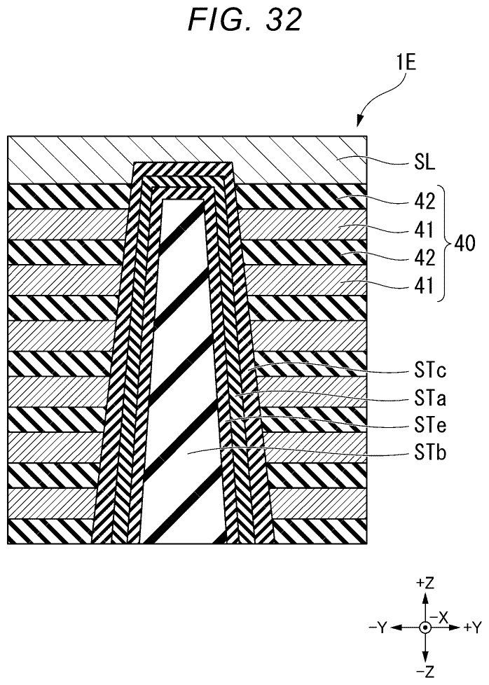

FIG. 32 is a cross-sectional view illustrating a fifth modification example of the semiconductor memory device according to the first embodiment. FIG. 32 is a diagram illustrating a portion of a semiconductor memory device 1E according to the fifth modification example different from that of the semiconductor memory device 1 according to the first embodiment. FIG. 32 does not illustrate the insulating film 47 in the conductive layer 41, and illustrates the conductive portion 45 and the barrier metal film 46 that form the conductive layer 41 and are integrated as the conductive layer 41. In addition, FIG. 32 does not illustrate the dividing portion ST that is embedded in a region where the conductive layer 41 is not present between the insulating layer 42 and the insulating layer 42.

As in the dividing portion ST of the semiconductor memory device 1 according to the first embodiment, the dividing portion ST of the semiconductor memory device 1E according to the fifth modification example includes the embedded insulating film STb, the diffusion barrier layer STa, and the side wall insulating film STc.

As illustrated in FIG. 32, the dividing portion ST in the semiconductor memory device 1E according to the fifth modification example includes a second diffusion barrier layer STe that is positioned between the embedded insulating film STb and the diffusion barrier layer STa in the Y direction, extends in the Z direction and the X direction, and includes a material different from that of the diffusion barrier layer STa.

As the material of the second diffusion barrier layer STe, a material that can be used for the above-described diffusion barrier layer STa can be used. In the semiconductor memory device 1E according to the fifth modification example, the second diffusion barrier layer STe and the diffusion barrier layer STa may be formed of different materials. Therefore, the second diffusion barrier layer STe and the diffusion barrier layer STa can prevent plural kinds of impurities from being diffused from the embedded insulating film STb to the conductive layer 41.

The dividing portion ST in the semiconductor memory device 1E according to the fifth modification example can be formed, for example, using the following method.

That is, after forming the diffusion barrier layer STa using the same method as the method of manufacturing the semiconductor memory device 1 according to the first embodiment, the second diffusion barrier layer STe can be formed using a material different from that of the diffusion barrier layer STa and using the same method as the method of forming the diffusion barrier layer STa in the method of manufacturing the semiconductor memory device 1 according to the first embodiment.

### 8.6 Sixth Modification Example of Semiconductor Memory Device

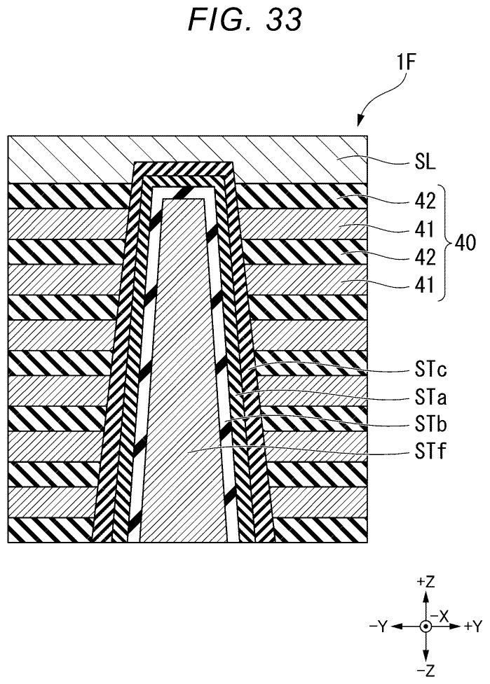

FIG. 33 is a cross-sectional view illustrating a sixth modification example of the semiconductor memory device according to the first embodiment. FIG. 33 is a diagram illustrating a portion of a semiconductor memory device 1F according to the sixth modification example different from that of the semiconductor memory device 1 according to the first embodiment. FIG. 33 does not illustrate the insulating film 47 in the conductive layer 41, and illustrates the conductive portion 45 and the barrier metal film 46 that form the conductive layer 41 and are integrated as the conductive layer 41. In addition, FIG. 33 does not illustrate the dividing portion ST that is embedded in a region where the conductive layer 41 is not present between the insulating layer 42 and the insulating layer 42.

As in the dividing portion ST of the semiconductor memory device 1 according to the first embodiment, the dividing portion ST of the semiconductor memory device 1F according to the sixth modification example includes the embedded insulating film STb, the diffusion barrier layer STa, and the side wall insulating film STc.

As illustrated in FIG. 33, the dividing portion ST in the semiconductor memory device 1F according to the sixth modification example includes a conductive layer STf that is positioned inside the embedded insulating film STb in the Y direction, extends in the Z direction and the X direction, and includes a material different from that of the embedded insulating film STb.

The conductive layer STf is formed of, for example, silicon doped with impurity. For example, the conductive layer STf may be formed of amorphous silicon, or may be formed of silicon germanium (GeSi) that is silicon to which germanium is added.

The dividing portion ST in the semiconductor memory device 1F according to the sixth modification example can be formed, for example, using the following method.

That is, using the same method as the method of forming the embedded insulating film STb in the method of manufacturing the semiconductor memory device 1 according to the first embodiment, the embedded insulating film STb can be formed along the inner surface of the groove 81 where the diffusion barrier layer STa is formed and along the surface of the stacked body 40 where the side wall insulating film STc and the diffusion barrier layer STa are formed (the surface of the stacked body 40 opposite to the source line SL) (refer to FIG. 16A).

Next, the inside of the groove 81 where the embedded insulating film STb is formed is embedded with the conductive layer STf by using a material for forming the conductive layer STf instead of the material for forming the embedded insulating film STb in the first modification example of the method of manufacturing the semiconductor memory device.

### 8.7 Seventh Modification Example of Semiconductor Memory Device

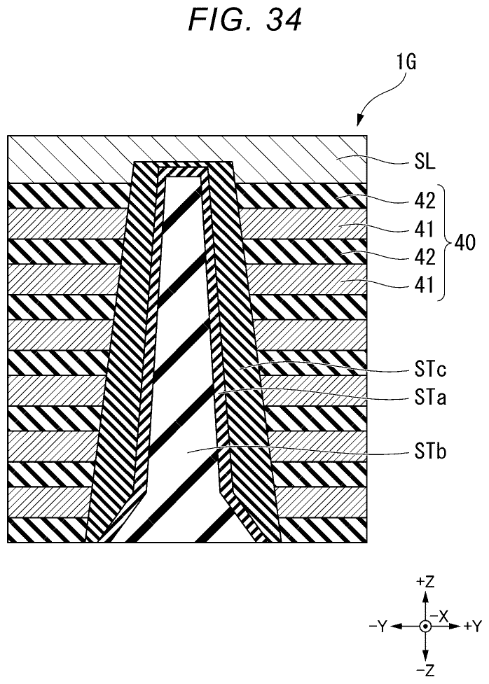

FIG. 34 is a cross-sectional view illustrating a seventh modification example of the semiconductor memory device according to the first embodiment. FIG. 34 is a diagram illustrating a portion of a semiconductor memory device 1G according to the seventh modification example different from that of the semiconductor memory device 1 according to the first embodiment. FIG. 34 does not illustrate the insulating film 47 in the conductive layer 41, and illustrates the conductive portion 45 and the barrier metal film 46 that form the conductive layer 41 and are integrated as the conductive layer 41. In addition, FIG. 34 does not illustrate the dividing portion ST that is embedded in a region where the conductive layer 41 is not present between the insulating layer 42 and the insulating layer 42.

As in the dividing portion ST of the semiconductor memory device 1 according to the first embodiment, the dividing portion ST of the semiconductor memory device 1G according to the seventh modification example includes the embedded insulating film STb, the diffusion barrier layer STa, and the side wall insulating film STc.

As illustrated in FIG. 34, in the dividing portion ST in the semiconductor memory device 1G according to the seventh modification example, the thickness of the side wall insulating film STc in the Y direction decreases toward one side (the lower side in FIG. 34) of the stacked body 40 in the Z direction, and the thickness of the embedded insulating film STb in the Y direction increases toward the one side of the stacked body 40 in the Z direction.

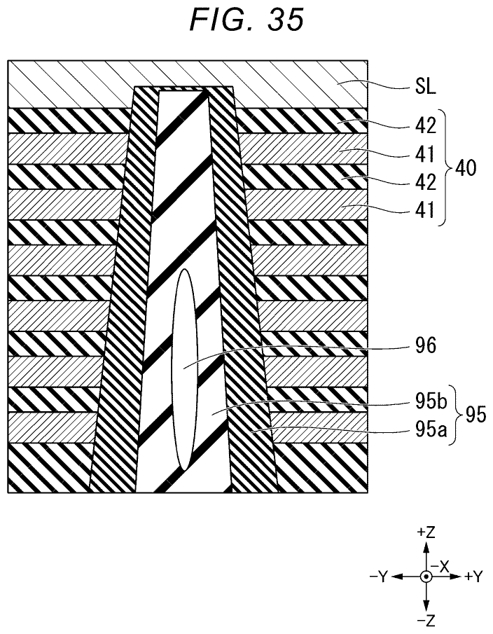

FIG. 35 is a cross-sectional view illustrating advantageous effects of the seventh modification example. A dividing portion 95 in the semiconductor memory device illustrated in FIG. 35 includes a side wall insulating film 95a corresponding to the side wall insulating film STc in the semiconductor memory device 1G according to the seventh modification example and an embedded insulating film 95b corresponding to the embedded insulating film STb in the semiconductor memory device 1E according to the fifth modification example.

In the dividing portion ST of the semiconductor memory device illustrated in FIG. 35, the thickness of the embedded insulating film 95b and the side wall insulating film 95a in the Y direction increases toward the one side (the lower side in FIG. 34) of the stacked body 40 in the Z direction.

In the dividing portion ST of the semiconductor memory device illustrated in FIG. 35, a cavity 96 is formed in the center portion of the embedded insulating film 95b in the Y direction. When the cavity 96 is formed in the dividing portion ST, the strength of the dividing portion ST decreases. In addition, impurity may be diffused to the conductive layer 41 from the cavity 96 formed in the dividing portion ST such that the reliability of the memory cell array 11 decreases.

On the other hand, in the dividing portion ST in the semiconductor memory device 1G according to the seventh modification example, the thickness of the side wall insulating film STc in the Y direction decreases toward one side (the lower side in FIG. 34) of the stacked body 40 in the Z direction, and the thickness of the embedded insulating film STb in the Y direction increases toward the one side of the stacked body 40 in the Z direction. Therefore, the embeddability of the embedded insulating film STb that is formed along the inner surface of the diffusion barrier layer STa after forming the diffusion barrier layer STa along the inner surface of the side wall insulating film STc is excellent. Accordingly, in the semiconductor memory device 1G according to the seventh modification example, a cavity is not likely to be formed in the embedded insulating film STb. Accordingly, in the semiconductor memory device 1G according to the seventh modification example, by forming the cavity in the embedded insulating film STb, a decrease in the strength of the dividing portion ST or diffusion of impurity from the cavity to the conductive layer 41 can be prevented.

Hereinabove, one embodiment and the plurality of examples are described. However, the embodiment and the examples are not limited to the above-described examples.

A semiconductor memory device according to at least one embodiment described above includes a stacked body and a dividing portion. The stacked body includes a plurality of conductive layers and a plurality of insulating layers, in which the plurality of conductive layers and the plurality of insulating layers are stacked one by one alternately in a first direction. The dividing portion penetrates the stacked body and extends in the first direction and in a second direction intersecting the first direction. When a direction intersecting the first direction and the second direction is a third direction, the dividing portion includes a first film and a second film. The first film extends in the first direction and the second direction and has insulating characteristics. The second film is positioned between the conductive layers and the first film in the third direction, extends in the first direction and the second direction, has a smaller thickness in the third direction than the first film, and includes a material different from that of the first film. With this configuration, electrical characteristics of the semiconductor memory device can be improved.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a stacked body including a plurality of conductive layers and a plurality of insulating layers, wherein the plurality of conductive layers and the plurality of insulating layers are alternately stacked on top of one another in a first direction; and
a dividing portion penetrating the stacked body and extending in the first direction and in a second direction intersecting the first direction,
wherein when a direction intersecting the first direction and the second direction is a third direction,
the dividing portion includes:
a first film extending in the first direction and the second direction and including a first insulating material; and
a second film positioned between the plurality of conductive layers and the first film in the third direction, extending in the first direction and the second direction, having a thinner thickness in the third direction than the first film, and including a second insulating material different from the first insulating material.

2. The semiconductor memory device according to claim 1, further comprising a third film positioned between the plurality of conductive layers and the second film in the third direction, extending in the first direction and the second direction, including a third insulating material different from the second insulating material.

3. The semiconductor memory device according to claim 2, wherein a thickness of the third film in the third direction is 5 nm to 10 nm.

4. The semiconductor memory device according to claim 1, wherein the second film includes silicon and nitrogen.

5. The semiconductor memory device according to claim 1, wherein the second film includes at least one of aluminum, hafnium, zirconium, or titanium.

6. The semiconductor memory device according to claim 1,
wherein when seen from the second direction,
the dividing portion includes a first end portion positioned on a first side in the third direction and a second end portion positioned on a second side in the third direction opposite to the first side, and
at least one of the first end portion or the second end portion extends in the third direction.

7. The semiconductor memory device according to claim 1,
wherein when seen from the first direction,
the dividing portion includes a first end portion positioned on a first side in the third direction and a second end portion positioned on a second side in the third direction opposite to the first side,
the first end portion includes a plurality of first arc portions adjacent to each other in the second direction, each of the first arc portions having a convex shape toward an outer side of the dividing portion in the third direction,
the second end portion includes a plurality of second arc portions adjacent to each other in the second direction, each of the second arc portions having a convex shape toward an outer side of the dividing portion in the third direction, and
the second film includes a plurality of third arc portions along the plurality of first arc portions and a plurality of fourth arc portions along the plurality of second arc portions.

8. The semiconductor memory device according to claim 1, further comprising a plurality of wirings disposed on a first side of the stacked body in the first direction,
wherein the second film includes a first portion extending in the first direction and the second direction in the dividing portion and a second portion extending in the third direction from an end portion of the first side of the first portion in the first direction and disposed between the stacked body and the plurality of wirings.

9. The semiconductor memory device according to claim 2,
wherein a thickness of the third film in the third direction decreases toward one side of the stacked body in the first direction, and
a thickness of the first film in the third direction increases toward the one side of the stacked body in the first direction.

10. The semiconductor memory device according to claim 1, further comprising:
a fourth film positioned between the first film and the second film in the third direction, extending in the first direction and the second direction, and including a third insulating material different from the second insulating material; and
a fifth film positioned between the first film and the fourth film in the third direction, extending in the first direction and the second direction, and including a fourth insulating material different from the first insulating material or the third insulating material.

11. A method of manufacturing a semiconductor memory device, the method comprising:
forming a stacked body including a plurality of first layers and a plurality of second layers alternately stacked in a first direction;
forming a groove penetrating the stacked body in the first direction and extending in a second direction intersecting the first direction;
replacing the first layers with a plurality of conductive layers, respectively;
forming a second film extending in the first direction and the second direction along an inner surface of the groove; and
forming a first film having a first insulating material, positioned on a side of the second film opposite to the conductive layer, and extending in the first direction and the second direction in the groove,
wherein when a direction intersecting the first direction and the second direction is a third direction,
the second film has a thinner thickness in the third direction than the first film and includes a second insulating material different from the first insulating material.

12. The method according to claim 11, wherein the second film includes silicon and nitrogen.

13. The method according to claim 11, wherein the second film includes at least one of aluminum, hafnium, zirconium, or titanium.

14. The method according to claim 11, wherein the first film includes a plurality of first portions protruding toward the conductive layers, respectively.

15. The method according to claim 14, wherein the second film includes a plurality of second portions protruding toward the conductive layers, respectively.

16. The method according to claim 15, wherein each of the second portions extends along a corresponding one of the first portions.
